(19) United States
(12) Patent Application Publication
(10) Pub. No.: US 2026/0221725 A1
(43) Pub. Date: Jul. 30, 2026

(54) NARROWING VERTICAL-CAVITY SURFACE-EMITTING LASER BEAM DIVERGENCE WITH DETUNED DISTRIBUTED BRAGG REFLECTOR

(71) Applicant: Lumentum Operations LLC, San Jose, CA (US)

(72) Inventors: Jun YANG, Cupertino, CA (US); Matthew Glenn PETERS, Menlo Park, CA (US)

(21) Appl. No.: 19/095,410

(22) Filed: Mar. 31, 2025

Related U.S. Application Data
(60) Provisional application No. 63/750,636, filed on Jan. 28, 2025.

(51) Int. Cl. H01S 5/183; H01S 5/30

(52) U.S. Cl. CPC H01S 5/18361; H01S 5/3095

(57) ABSTRACT

An emitter includes a bottom distributed Bragg reflector (DBR) mirror characterized by a first reflectance curve that defines a first optical stop-band having a first center wavelength substantially aligned with an emission wavelength; a top DBR mirror arranged characterized by a second reflectance curve that defines a second optical stop-band having a second center wavelength substantially aligned with the emission wavelength; an active region configured to generate laser light at the emission wavelength; and a detuned DBR arranged between the bottom DBR mirror and the active region or between the top DBR mirror and the active region. The bottom DBR mirror, the top DBR mirror, the detuned DBR, and the active region define an optical cavity of the emitter. The detuned DBR is configured to increase an effective cavity length of the optical cavity.

### CROSS-REFERENCE TO RELATED APPLICATION

This Patent Application claims priority to U.S. patent application Ser. No. 63/750,636, filed on Jan. 28, 2025, and entitled NARROWING VERTICAL CAVITY SURFACE EMITTING LASER BEAM DIVERGENCE WITH DETUNED DISTRIBUTED BRAGG REFLECTOR.” The disclosure of the prior Application is considered part of and is incorporated by reference into this Patent Application.

### TECHNICAL FIELD

The present disclosure relates generally to vertical-cavity surface-emitting laser (VCSEL) device and to narrowing VCSEL beam divergence with a detuned distributed Bragg reflector.

### BACKGROUND

A VCSEL is a type of semiconductor laser diode (e.g., a laser resonator) with laser beam emission perpendicular to a top surface or a bottom surface of the device. VCSELs typically include two distributed Bragg reflector (DBR) mirrors arranged parallel to a wafer surface with an active region arranged between the two DBR mirrors. The active region includes one or more quantum wells for laser light generation. VCSELs are widely used in various applications, such as data communications, sensing, and optical interconnects, due to advantages over other types of lasers. For example, VCSELs typically have lower power consumption (e.g., VCSELs require much lower power to operate than other types of lasers, making them more energy-efficient and cost-effective), are capable of high-speed operation (e.g., making VCSELs ideal for data communications and other applications that require high-speed signal transmission), have narrow beam divergence (e.g., the narrow beam divergence of VCSELs allows for high coupling efficiency with optical fibers and other components, making VCSELs easier to integrate into optical systems), and have high reliability (e.g., VCSELs have a long operating lifetime and are less prone to failure than other types of lasers).

Different applications, such as three-dimensional sensing and data communications, may use semiconductor lasers emitting at different wavelength bands. For example, short-range communications may use VCSELs emitting at around 850 nm, whereas long-range communications may use VCSELs emitting above 1.3 μm or even above 1.5 μm. Three-dimensional sensing applications, such as light detection and ranging (LiDAR), may use VCSELs emitting at different wavelengths, such as 905 nm and 940 nm, to enable varied functions.

A typical VCSEL has a sandwich structure mainly consisting of a top DBR, a bottom DBR, and an active region (e.g., an active layer) arranged between the top DBR and the bottom DBR. Each DBR is made of multiple alternatively stacked high-index layers and low-index layers, and each layer has an optical thickness of an odd integer multiple of ¼-lambda (λ/4, 3λ/4, . . . ), where an optical thickness of one lambda is the length of one wavelength divided by the refractive index. “High-index” means a relatively higher value of an optical refractive index, and “low-index” means a relatively lower value of an optical refractive index. Optionally, a DBR may include gradient layers that provide a smoother transition between different energy bands corresponding to high-index and low-index semiconductor materials. The top DBR, the active region, and the bottom DBR form an optical cavity with gain material.

### SUMMARY

In some implementations, an emitter includes a bottom distributed Bragg reflector (DBR) mirror, the bottom DBR mirror characterized by a first reflectance curve that defines a first optical stop-band having a first center wavelength substantially aligned with an emission wavelength; a top DBR mirror arranged on the bottom DBR mirror, the top DBR mirror characterized by a second reflectance curve that defines a second optical stop-band having a second center wavelength substantially aligned with the emission wavelength; an active region formed by one or more active layers comprising one or more junctions, each junction including one or more quantum wells, wherein the active region is configured to generate laser light at the emission wavelength, and wherein the active region is arranged between the top DBR mirror and the bottom DBR mirror; a first detuned DBR arranged between the bottom DBR mirror and the active region or between the top DBR mirror and the active region, the first detuned DBR characterized by a third reflectance curve that defines a third optical stop-band and a minimum reflection region, wherein the third optical stop-band is offset from the emission wavelength, and wherein the minimum reflection region is aligned with the emission wavelength; and an optical output arranged over the top DBR mirror, wherein the emitter is configured to emit the laser light via the optical output.

In some implementations, an emitter includes a bottom DBR mirror, the bottom DBR mirror characterized by a first reflectance curve that defines a first optical stop-band having a first center wavelength substantially aligned with an emission wavelength; a top DBR mirror arranged on the bottom DBR mirror, the top DBR mirror characterized by a second reflectance curve that defines a second optical stop-band having a second center wavelength substantially aligned with the emission wavelength; an active region formed by one or more active layers comprising one or more junctions, each junction including one or more quantum wells, wherein the active region is configured to generate laser light at the emission wavelength, and wherein the active region is arranged between the top DBR mirror and the bottom DBR mirror; a first detuned DBR arranged between the bottom DBR mirror and the active region or between the top DBR mirror and the active region, wherein the bottom DBR mirror, the top DBR mirror, the first detuned DBR, and the active region define an optical cavity of the emitter, and wherein the first detuned DBR is configured to increase an effective cavity length of the optical cavity; and an optical output arranged over the top DBR mirror, wherein the emitter is configured to emit the laser light via the optical output.

In some implementations, an emitter includes a bottom DBR mirror, the bottom DBR mirror characterized by a first reflectance curve that defines a first optical stop-band having a first center wavelength substantially aligned with an emission wavelength; a top DBR mirror arranged on the bottom DBR mirror, the top DBR mirror characterized by a second reflectance curve that defines a second optical stop-band having a second center wavelength substantially aligned with the emission wavelength; an active region formed by one or more active layers comprising one or more junctions, each junction including one or more quantum wells, wherein the active region is configured to generate laser light at the emission wavelength, and wherein the active region is arranged between the top DBR mirror and the bottom DBR mirror; a first detuned DBR arranged between the bottom DBR mirror and the active region or between the top DBR mirror and the active region, the first detuned DBR characterized by a third reflectance curve; a second detuned DBR arranged between the bottom DBR mirror and the active region or between the top DBR mirror and the active region, the second detuned DBR characterized by a fourth reflectance curve, wherein the first detuned DBR and the second detuned DBR, in combination, are configured to induce, in an optical field of the emission wavelength propagating through the first detuned DBR and the second detuned DBR, a phase deviation substantially equal to π; and an optical output arranged over the top DBR mirror, wherein the emitter is configured to emit the laser light via the optical output.

### BRIEF DESCRIPTION OF THE DRAWINGS

FIGS. 1A and 1B are diagrams depicting a top view of an example emitter and a cross-sectional view of example emitter along the line X-X, respectively.

FIG. 2A shows an emitter stacked structure of an emitter according to one or more implementations.

FIG. 2B shows an emitter stacked structure of an emitter according to one or more implementations.

FIG. 3 shows a graph of reflectance curve versus an optical thickness deviation per half-wave.

FIGS. 4A-4C show example detuning schematics of a 10-pair DBR.

FIGS. 5A-5C show example detuning schematics of a 10-pair DBR.

FIGS. 6A-6D show example detuning schematics of a 10-pair DBR.

FIGS. 7A-7B show example detuning schematics of a 10-pair DBR.

FIGS. 8A-8C show example detuning schematics of a 10-pair DBR.

FIGS. 9A-9D show example detuning schematics of a 10-pair DBR.

FIGS. 10A-10B show example detuning schematics of an optical thickness of λ0/2 deviation relative to a 10-pair DBR, including a spacer.

FIG. 11 shows a diagram including a refractive index curve and an optical field intensity curve of a multi-junction VCSEL emitter according to one or more implementations.

FIG. 12 shows a diagram including a refractive index curve and an optical field intensity curve of a multi-junction VCSEL emitter according to one or more implementations.

FIG. 13 shows a diagram including a refractive index curve and an optical field intensity curve of a multi-junction VCSEL emitter according to one or more implementations.

FIG. 14 shows a diagram including a refractive index curve and an optical field intensity curve of a multi-junction VCSEL emitter according to one or more implementations.

FIG. 15 shows a diagram including a refractive index curve and an optical field intensity curve of a multi-junction VCSEL emitter according to one or more implementations.

FIG. 16 shows a diagram including a refractive index curve and an optical field intensity curve of a multi-junction VCSEL emitter according to one or more implementations.

### DETAILED DESCRIPTION

The following detailed description of example implementations refers to the accompanying drawings. The same reference numbers in different drawings may identify the same or similar elements.

Multi-junction VCSEL emitters, which have multiple active regions connected by tunnel junctions, are a rapidly growing class of high-brightness laser sources for three-dimensional (3D) sensing and automotive light detection and ranging (LiDAR). A narrower beam divergence is advantageous to provide higher brightness per angle.

Some implementations provide a detuned distributed Bragg reflector (DBR) to reduce reflection and elongate an effective cavity length of a multi-junction VCSEL emitter, thereby narrowing a beam divergence of the multi-junction VCSEL emitter. The detuned DBR may be configured such that a minimum reflection region (e.g., a pass-band region) of the detuned DBR coincides with an emission (resonant) wavelength of the multi-junction VCSEL emitter, and such that an optical field of emitted light undergoes a phase deviation of ±π or close to ±π, resulting in narrower beam divergence. In some implementations, two or more detuned DBRs may be combined to form a minimum reflection region that coincides with the emission (resonant) wavelength of the multi-junction VCSEL emitter, and such that an optical field of emitted light undergoes a phase deviation of ±π or close to ±π, resulting in narrower beam divergence.

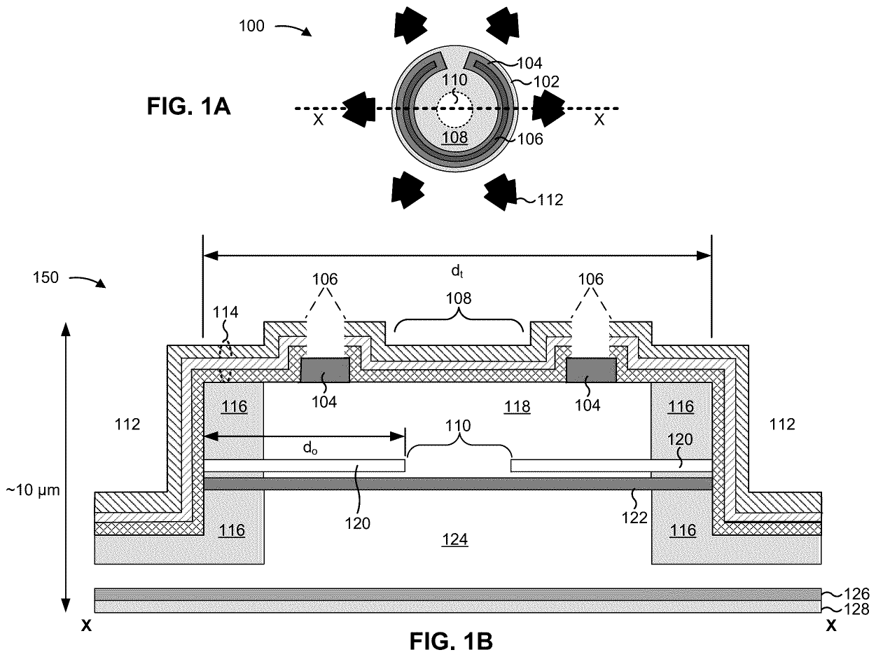

FIGS. 1A and 1B are diagrams depicting a top view of an example emitter 100 and a cross-sectional view 150 of example emitter 100 along the line X-X, respectively. As shown in FIG. 1A, emitter 100 may include a set of emitter layers constructed in an emitter architecture. In some implementations, emitter 100 may correspond to one or more vertical-emitting devices (e.g., VCSEL devices) described herein.

As shown in FIG. 1A, emitter 100 may include an implant protection layer 102 that is circular in shape in this example. In some implementations, implant protection layer 102 may have another shape, such as an elliptical shape, a polygonal shape, or the like. Implant protection layer 102 is defined based on a space between sections of implant material (not shown) included in emitter 100.

As shown by the medium gray and dark gray areas in FIG. 1A, emitter 100 includes an ohmic metal layer 104 (e.g., a P-Ohmic metal layer or an N-Ohmic metal layer) that is constructed in a partial ring-shape (e.g., with an inner radius and an outer radius). The medium gray area shows an area of ohmic metal layer 104 covered by a protective layer (e.g. a dielectric layer or a passivation layer) of emitter 100 and the dark gray area shows an area of ohmic metal layer 104 exposed by via 106, described below. As shown, ohmic metal layer 104 overlaps with implant protection layer 102. Such a configuration may be used, for example, in the case of a P-up/top-emitting emitter 100. In the case of a bottom-emitting emitter 100, the configuration may be adjusted as needed.

Not shown in FIG. 1A, emitter 100 includes a protective layer in which via 106 is formed (e.g., etched). The dark gray area shows an area of ohmic metal layer 104 that is exposed by via 106 (e.g., the shape of the dark gray area may be a result of the shape of via 106) while the medium grey area shows an area of ohmic metal layer 104 that is covered by some protective layer. The protective layer may cover all of the emitter other than the vias. As shown, via 106 is formed in a partial ring-shape (e.g., similar to ohmic metal layer 104) and is formed over ohmic metal layer 104 such that metallization on the protection layer contacts ohmic metal layer 104. In some implementations, via 106 and/or ohmic metal layer 104 may be formed in another shape, such as a full ring-shape or a split ring-shape.

As further shown, emitter 100 includes an optical aperture 108 in a portion of emitter 100 within the inner radius of the partial ring-shape of ohmic metal layer 104. Emitter 100 emits a laser beam via optical aperture 108. As further shown, emitter 100 also includes a current confinement aperture 110 (e.g., an oxide aperture formed by an oxidation layer of emitter 100 (not shown)). Current confinement aperture 110 is formed below optical aperture 108.

As further shown in FIG. 1A, emitter 100 includes a set of trenches 112 (e.g., oxidation trenches) that are spaced (e.g., equally, unequally) around a circumference of implant protection layer 102. How closely trenches 112 can be positioned relative to the optical aperture 108 is dependent on the application, and is typically limited by implant protection layer 102, ohmic metal layer 104, via 106, and manufacturing tolerances.

The number and arrangement of layers shown in FIG. 1A are provided as an example. In practice, emitter 100 may include additional layers, fewer layers, different layers, or differently arranged layers than those shown in FIG. 1A. For example, while emitter 100 includes a set of six trenches 112, in practice, other configurations are possible, such as a compact emitter that includes five trenches 112, seven trenches 112, or another quantity of trenches. In some implementations, trench 112 may encircle emitter 100 to form a mesa structure dt. As another example, while emitter 100 is a circular emitter design, in practice, other designs may be used, such as a rectangular emitter, a hexagonal emitter, an elliptical emitter, or the like. Additionally, or alternatively, a set of layers (e.g., one or more layers) of emitter 100 may perform one or more functions described as being performed by another set of layers of emitter 100, respectively.

Notably, while the design of emitter 100 is described as including a VCSEL, other implementations are possible. For example, the design of emitter 100 may apply in the context of another type of optical device, such as a light emitting diode (LED), or another type of vertical emitting (e.g., top emitting or bottom emitting) optical device. Additionally, the design of emitter 100 may apply to emitters of any wavelength, power level, and/or emission profile. In other words, emitter 100 is not particular to an emitter with a given performance characteristic.

As shown in FIG. 1B, the example cross-sectional view may represent a cross-section of emitter 100 that passes through, or between, a pair of trenches 112 (e.g., as shown by the line labeled “X-X” in FIG. 1A). As shown, emitter 100 may include a backside cathode layer 128, a substrate layer 126, a bottom mirror 124 (e.g., a bottom DBR mirror), an active region 122, an oxidation layer 120, a top mirror 118 (e.g., a top DBR mirror), an implant isolation material 116, a protective layer 114 (e.g. a dielectric passivation/mirror layer), and an ohmic metal layer 104. As shown, emitter 100 may have, for example, a total height that is approximately 10 μm.

Backside cathode layer 128 may include a layer that makes electrical contact with substrate layer 126. For example, backside cathode layer 128 may include an annealed metallization layer, such as an AuGeNi layer, a PdGeAu layer, or the like.

Substrate layer 126 may include a base substrate layer upon which epitaxial layers are grown. For example, substrate layer 126 may include a semiconductor layer, such as a GaAs layer, an InP layer, and/or another type of semiconductor layer.

Bottom mirror 124 may include a bottom reflector layer of emitter 100. For example, bottom mirror 124 may include a DBR.

Active region 122 may include a layer that confines electrons and defines an emission wavelength of emitter 100. For example, active region 122 may be a quantum well. The active region 122 is arranged between the top mirror 118 and bottom mirror 124. In some implementations, active region 122 may be formed by one or more active layers comprising one or more junctions, each junction including one or more quantum wells. The active region may generate laser light at an emission wavelength. The top mirror 118, the bottom mirror, and the active region 122 define an optical cavity of the emitter 100.

Oxidation layer 120 may include an oxide layer that provides optical and electrical confinement of emitter 100. In some implementations, oxidation layer 120 may be formed as a result of wet oxidation of an epitaxial layer. For example, oxidation layer 120 may be an Al2O3 layer formed as a result of oxidation of an AlAs or AlGaAs layer. Trenches 112 may include openings that allow oxygen (e.g., dry oxygen, wet oxygen) to access the epitaxial layer from which oxidation layer 120 is formed.

Current confinement aperture 110 may include an optically active aperture defined by oxidation layer 120 (or one or more oxidation layers 120). Current confinement aperture 110 may be formed through oxidation layer 120 to provide current confinement and optical index guiding in the active region 122. A size of current confinement aperture 110 may range, for example, from approximately 4 μm to approximately 20 μm. In some implementations, a size of current confinement aperture 110 may depend on a distance between trenches 112 that surround emitter 100. For example, trenches 112 may be etched to expose the epitaxial layer from which oxidation layer 120 is formed. Here, before protective layer 114 is formed (e.g., deposited), oxidation of the epitaxial layer may occur for a particular distance (e.g., identified as do in FIG. 1B) toward a center of emitter 100, thereby forming oxidation layer 120 and current confinement aperture 110. In some implementations, current confinement aperture 110 may include an oxide aperture. Additionally, or alternatively, current confinement aperture 110 may include an aperture associated with another type of current confinement technique, such as an etched mesa, a region without ion implantation, lithographically defined intra-cavity mesa and regrowth, or the like.

Top mirror 118 may include a top reflector layer of emitter 100. For example, top mirror 118 may include a DBR.

Implant isolation material 116 may include a material that provides electrical isolation. For example, implant isolation material 116 may include an ion implanted material, such as a hydrogen/proton implanted material or a similar implanted element to reduce conductivity. In some implementations, implant isolation material 116 may define implant protection layer 102.

Protective layer 114 may include a layer that acts as a protective passivation layer and which may act as an additional DBR. For example, protective layer 114 may include one or more sub-layers (e.g., a dielectric passivation layer and/or a mirror layer, a SiO2 layer, a Si3N4 layer, an Al2O3 layer, or other layers) deposited (e.g., by chemical vapor deposition, atomic layer deposition, or other techniques) on one or more other layers of emitter 100.

As shown, protective layer 114 may include one or more vias 106 that provide electrical access to ohmic metal layer 104. For example, via 106 may be formed as an etched portion of protective layer 114 or a lifted-off section of protective layer 114. Optical aperture 108, corresponding to an optical output from which light is emitted to an environment, may include a portion of protective layer 114 over current confinement aperture 110 through which light may be emitted.

Ohmic metal layer 104 may include a layer that makes electrical contact through which electrical current may flow. For example, ohmic metal layer 104 may include a Ti and Au layer, a Ti and Pt layer and/or an Au layer, or the like, through which electrical current may flow (e.g., through a bond pad (not shown) that contacts ohmic metal layer 104 through via 106). Ohmic metal layer 104 may be P-ohmic, N-ohmic, or other forms known in the art. Selection of a particular type of ohmic metal layer 104 may depend on the architecture of the emitters and is well within the knowledge of a person skilled in the art. Ohmic metal layer 104 may provide ohmic contact between a metal and a semiconductor and/or may provide a non-rectifying electrical junction and/or may provide a low-resistance contact. In some implementations, emitter 100 may be manufactured using a series of steps. For example, bottom mirror 124, active region 122, oxidation layer 120, and top mirror 118 may be epitaxially grown on substrate layer 126, after which ohmic metal layer 104 may be deposited on top mirror 118. Next, trenches 112 may be etched to expose oxidation layer 120 for oxidation. Implant isolation material 116 may be created via ion implantation, after which protective layer 114 may be deposited. Via 106 may be etched in protective layer 114 (e.g., to expose ohmic metal layer 104 for contact). Plating, seeding, and etching may be performed, after which substrate layer 126 may be thinned and/or lapped to a target thickness. Finally, backside cathode layer 128 may be deposited on a bottom side of substrate layer 126.

The bottom mirror 124 may be characterized by a first reflectance curve that defines a first optical stop-band having a first center wavelength substantially aligned with the emission wavelength of the active region 122. The top mirror 118 may be characterized by a second reflectance curve that defines a second optical stop-band having a second center wavelength substantially aligned with the emission wavelength of the active region 122. Accordingly, the bottom mirror 124 and the top mirror 118 may be referred to as “tuned DBRs” or “regular DBRs.”

Additionally, the emitter 100 may include a detuned DBR arranged between the bottom mirror 124 and the active region 122 or between the top mirror 118 and the active region 122. In some implementations, the emitter 100 may include two or more detuned DBRs. For example, the two or more detuned DBRs may be arranged between the bottom mirror 124 and the active region 122 or between the top mirror 118 and the active region 122. In some implementations, a first detuned DBR may be arranged between the bottom mirror 124 and the active region 122, and a second detuned DBR may be arranged between the top mirror 118 and the active region 122. Detuned DBRs do not have an optical stop-band having a center wavelength substantially aligned with the emission wavelength of the active region 122. The one or more detuned DBR may increase an effective cavity length of the optical cavity, thereby narrowing a beam divergence of the emitter 100. In some implementations, emitter 100 may be a multi-junction VCSEL emitter.

The number, arrangement, thicknesses, order, symmetry, or the like, of layers shown in FIG. 1B is provided as an example. In practice, emitter 100 may include additional layers, fewer layers, different layers, differently constructed layers, or differently arranged layers than those shown in FIG. 1B. Additionally, or alternatively, a set of layers (e.g., one or more layers) of emitter 100 may perform one or more functions described as being performed by another set of layers of emitter 100 and any layer may comprise more than one layer.

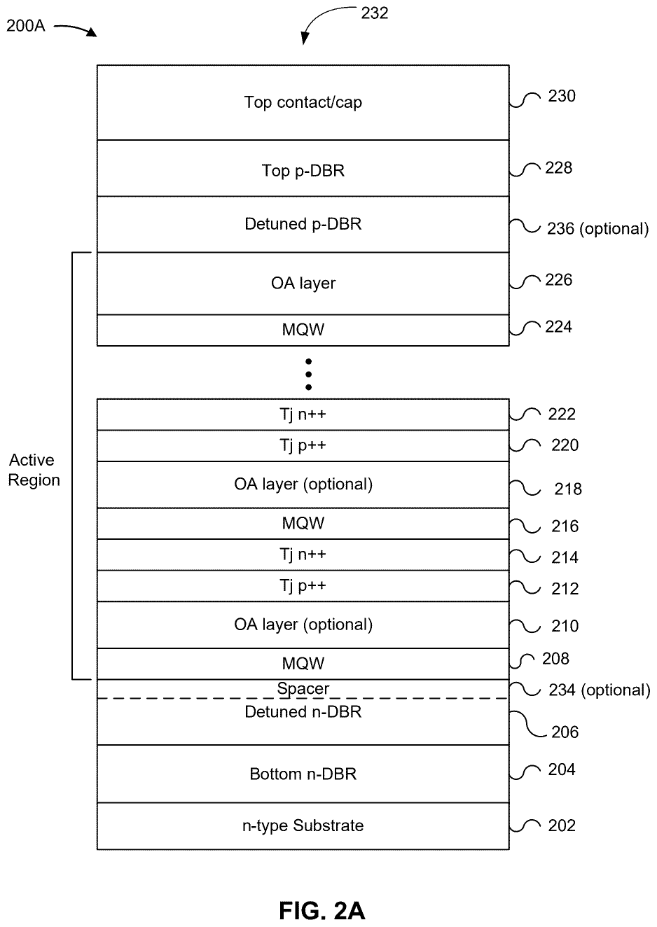

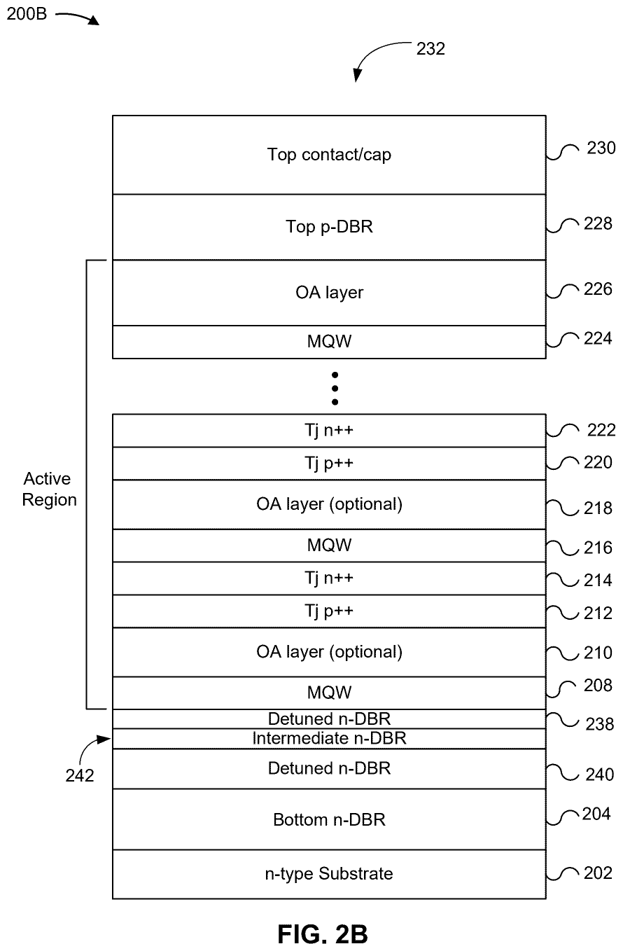

FIG. 2A shows an emitter stacked structure 200A of an emitter according to one or more implementations. The emitter may be one emitter of an emitter array that includes a plurality of emitters. Thus, the emitter stacked structure 200A may be used in each emitter of the emitter array. The emitter stacked structure 200A may include a substrate layer 202, a bottom DBR mirror 204, a detuned DBR 206, a multi-quantum well (MQW) 208 (e.g., an active region), an optical aperture layer 210 defining a current confinement aperture, a tunnel junction layer 212 (e.g., with a p++ doping), a tunnel junction layer 214 (e.g., with an n++ doping), an MQW 216, an optical aperture layer 218 defining a current confinement aperture, a tunnel junction layer 220 (e.g., with a p++ doping), a tunnel junction layer 222 (e.g., with an n++ doping), an MQW 224, an optical aperture layer 226 defining a current confinement aperture, a top DBR mirror 228, and a top contact layer 230 (e.g., a metal layer or cap). Thus, the emitter may be a multi-junction VCSEL emitter that has multiple active regions connected by tunnel junctions. An optical output 232 may be arranged over the top DBR mirror 228 such that the emitter is configured to emit the laser light via the optical output 232.

A total active region may be defined by a bottom-most MQW (e.g., MQW 208) and a top-most MQW (e.g., MQW 224). In the example shown in FIG. 2A, the detuned DBR 206 is arranged between the bottom DBR mirror 204 and the active region (e.g., the total active region). However, in some implementations, the detuned DBR 206 may be arranged between the top DBR mirror 228 and the active region (e.g., the total active region). In some implementations, the emitter stacked structure 200A may include two or more detuned DBRs. For example, the two or more detuned DBRs may be arranged between the bottom DBR mirror 204 and the active region or between the top DBR mirror 228 and the active region. In some implementations, a first detuned DBR may be arranged between the bottom DBR mirror 204 and the active region, and a second detuned DBR may be arranged between the top DBR mirror 228 and the active region.

The bottom DBR mirror 204 may be characterized by a first reflectance curve that defines a first optical stop-band having a first center wavelength substantially aligned with an emission wavelength of laser light generated by the active region. The top DBR mirror 228 may be characterized by a second reflectance curve that defines a second optical stop-band having a second center wavelength substantially aligned with the emission wavelength. The active region, arranged between the top DBR mirror 228 and the bottom DBR mirror 204, may be formed by one or more active layers comprising one or more junctions, each junction including one or more quantum wells. The active region is configured to generate laser light at the emission wavelength.

The detuned DBR 206 is arranged between the bottom DBR mirror 204 and the active region or between the top DBR mirror 228 and the active region. The detuned DBR 206 characterized by a third reflectance curve that defines a third optical stop-band and a minimum reflection region. The third optical stop-band is offset from the emission wavelength. In other words, the third optical stop-band is offset from a Braggs condition. Moreover, the minimum reflection region is aligned with the emission wavelength. The minimum reflection region may be a pass-band that is aligned with the emission wavelength. The bottom DBR mirror 204, the top DBR mirror 228, the detuned DBR 206, and the active region define an optical cavity of the emitter. Thus, the detuned DBR 206 is configured to increase an effective cavity length of the optical cavity, thereby narrowing a beam divergence of the emitter.

In some implementations, the minimum reflection region is a first minimum reflection region located directly between the third optical stop-band and a first side-lobe of the third reflectance curve. In this case, the detuned DBR 206 is configured to cause an envelope of an optical field peak intensity to exhibit a gradually-changing outline with single peak over a length of the detuned DBR 206. When the emission wavelength is not within the optical stop-band but falls exactly at a valley between a main stop-band and a first side-lobe, the light experiences minimum reflection, and a phase deviation of the optical field is π or substantially close to π.

In some implementations, the minimum reflection region is a second minimum reflection region located directly between a first side-lobe of the third reflectance curve and a second side-lobe of the third reflectance curve. In this case, the detuned DBR 206 is configured to cause an envelope of an optical field peak intensity to exhibit a gradually-changing outline with two peaks over a length of the detuned DBR 206.

The detuned DBR 206 may be configured to cause an optical field peak intensity over a length of the detuned DBR 206 to firstly decrease based on light entering the detuned DBR 206 from the active region, subsequently increase to form at least one peak as the light propagates through the detuned DBR 206, and subsequently decrease as the light exists the detuned DBR 206.

In some implementations, the detuned DBR 206 has an optical thickness deviation that is offset from a half-wavelength integer of the emission wavelength.

In some implementations, the detuned DBR 206 includes a plurality of high and low refractive index layer pairs, and the detuned DBR 206 has a total optical thickness that is evenly distributed among the plurality of high and low refractive index layer pairs.

In some implementations, the detuned DBR 206 includes a plurality of high and low refractive index layer pairs, and the detuned DBR 206 has a total optical thickness that is unevenly distributed among the plurality of high and low refractive index layer pairs.

In some implementations, the detuned DBR 206 induces, in an optical field of the emission wavelength propagating through the detuned DBR 206, a phase deviation substantially equal to π or substantially equal to an integer of π (e.g., 2π, 3π, etc.).

In some implementations, the minimum reflection region of the detuned DBR 206 is not aligned with the emission wavelength. Instead, a spacer 234 may be arranged proximate to the detuned DBR 206, and the detuned DBR 206 and the spacer 234, in combination, may be configured to induce a reflectance curve defining a pass-band or a minimum reflection region that is aligned with the emission wavelength. The detuned DBR 206 and the spacer 234, in combination, may be configured to induce, in an optical field of the emission wavelength propagating through the spacer 234 and the detuned DBR 206, a phase deviation substantially equal to π. Thus, the detuned DBR 206 and the spacer 234 are configured to increase an effective cavity length of the optical cavity.

In some implementations, the detuned DBR 206 is a first detuned DBR arranged between the bottom DBR mirror 204 and the active region, and the emitter stacked structure 200A includes a second detuned DBR 236 arranged between the top DBR mirror 228 and the active region. The second detuned DBR 236 may be characterized by a fourth reflectance curve that defines a fourth optical stop-band and a further minimum reflection region (e.g., a further pass-band). The fourth optical stop-band is offset from the emission wavelength. Additionally, the further minimum reflection region of the second detuned DBR is aligned with the emission wavelength. The further minimum reflection region may be located at a first minimum reflection region or a second minimum reflection region of the fourth reflectance curve. Accordingly, the first detuned DBR 206 and the second detuned DBR 236 are configured to increase an effective cavity length of the emitter, thereby narrowing a beam divergence of the emitter.

In some implementations, the first detuned DBR 206 and the second detuned DBR 236, in combination, may be configured to induce, in an optical field of the emission wavelength propagating through the first detuned DBR 206 and the second detuned DBR 236, a phase deviation substantially equal to π.

A detuning scheme could also be implemented by splitting the detuned DBRs into multiple different segments, and/or with different refractive index contrasts or doping contrasts. Also, the optical thickness detuning distributed through the detuning DBRs may not be even.

As indicated above, FIG. 2A is provided as an example. Other examples may differ from what is described with regard to FIG. 2A.

FIG. 2B shows an emitter stacked structure 200B of an emitter according to one or more implementations. The emitter may be one emitter of an emitter array that includes a plurality of emitters. Thus, the emitter stacked structure 200B may be used in each emitter of the emitter array. The emitter stacked structure 200B may be similar to the emitter stacked structure 200A described in connection with FIG. 2A, except that a first detuned DBR 238 and a second detuned DBR 240 are arranged on a same side of the active region, as opposed to opposite sides of the active region. In the example shown in FIG. 2B, the first detuned DBR 238 and the second detuned DBR 240 are arranged between the bottom DBR mirror 204 and the active region. Alternatively, the first detuned DBR 238 and the second detuned DBR 240 may be arranged between the top DBR mirror 228 and the active region. The first detuned DBR 238 may be arranged closer to the active region than the second detuned DBR 240. The first detuned DBR 238 and the second detuned DBR 240 may have different detuning properties, such as a different number of DBR pairs, a different total optical thickness, different refractive index contrast, different doping contrast, and/or a different phase deviation. A refractive index contrast may refer to a difference between refractive indices of the high-index and low-index layers. For example, a relatively small difference between refractive indices of the high-index and low-index layers may be referred to as “low contrast,” whereas a relatively large difference between refractive indices of the high-index and low-index layers may be referred to as “high contrast.” A doping contrast may refer to a difference between different doping level in high-index and low-index DBR layers or different segments. In some cases, DBR pairs may be simply referred to as “pairs.”

The first detuned DBR 238 is characterized by a third reflectance curve. The second detuned DBR 240 is characterized by a fourth reflectance curve. The first detuned DBR 238 and the second detuned DBR 240, in combination, may be configured to induce, in an optical field of the emission wavelength propagating through the first detuned DBR 238 and the second detuned DBR 240, a phase deviation substantially equal to π. Accordingly, the first detuned DBR 238 and the second detuned DBR 240 are configured to increase an effective cavity length of the emitter, thereby narrowing a beam divergence of the emitter.

In some implementations, the first detuned DBR 238 may be configured to induce, in the optical field of the emission wavelength propagating through the first detuned DBR 238, a phase deviation substantially equal to π/2, and the second detuned DBR 240 may be configured to induce, in the optical field of the emission wavelength propagating through the second detuned DBR 240, a phase deviation substantially equal to π/2.

The first detuned DBR 238 and the second detuned DBR 240, in combination, may be configured to induce a reflectance curve defining a pass-band or a minimum reflection region that is aligned with the emission wavelength.

In some implementations, the first detuned DBR 238 and the second detuned DBR 240, in combination, are configured to cause an optical field peak intensity over a combined length of the first detuned DBR 238 and the second detuned DBR 240 to firstly decrease based on light entering the first detuned DBR 238 from the active region, subsequently increase to form at least one peak as the light propagates through the second detuned DBR 240, and subsequently decrease as the light exists the second detuned DBR 240.

In some implementations, an intermediate DBR mirror 242 may be arranged between the first detuned DBR 238 and the second detuned DBR 240. The intermediate DBR mirror 242 may be a regular DBR that is characterized by a fifth reflectance curve that defines a fifth optical stop-band having a fifth center wavelength substantially aligned with the emission wavelength. The first detuned DBR 238, the second detuned DBR 240, and the intermediate DBR mirror 242, in combination, may be configured to induce a reflectance curve defining a pass-band or a minimum reflection region that is aligned with the emission wavelength. Accordingly, the first detuned DBR 238, the second detuned DBR 240, and the intermediate DBR mirror 242 are configured to increase an effective cavity length of the emitter, thereby narrowing a beam divergence of the emitter.

As indicated above, FIG. 2B is provided as an example. Other examples may differ from what is described with regard to FIG. 2B.

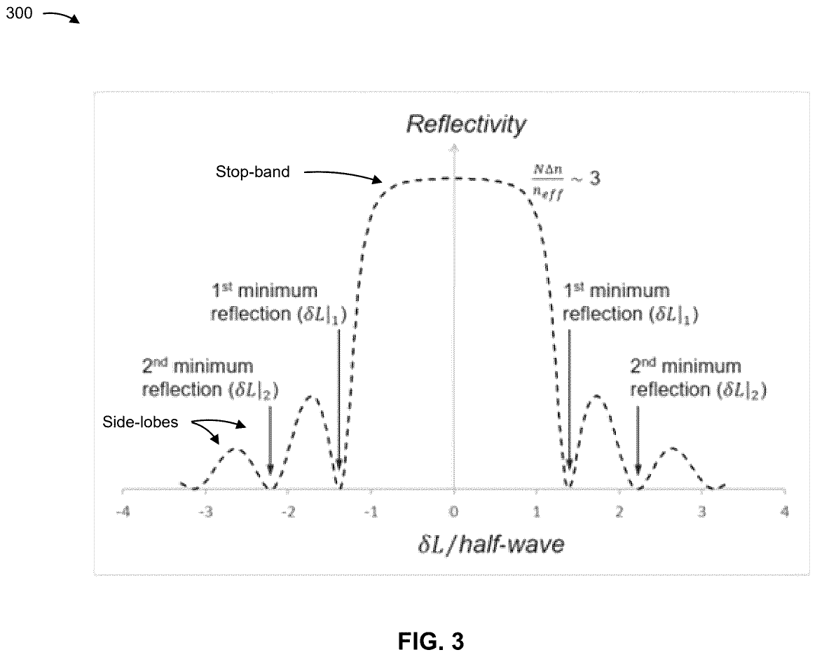

FIG. 3 shows a graph 300 of reflectance curve versus an optical thickness deviation δL per half-wave. In the example shown in FIG. 3, a DBR may be characterized by a reflectance factor NΔn/n_{eff}, where N is a number of DBR pairs, Δn=n_{H}-n_{L}, is a difference in refractive index between high and low refractive index layers, and n_{eff}=2n_{H}n₁/(n_{H}+n_{L}), n_{L}), is an effective refractive index, n_{H} and n_{L} are the refractive indices of the high and low refractive index layers, respectively. The reflectance curve includes an optical stop-band, multiple side-lobes, and multiple minimum reflection regions or pass-bands. A first minimum reflection region is located directly between the optical stop-band and a first side-lobe of the reflectance curve. The optical thickness detuning δL|₁ corresponding to the first minimum reflection can be estimated by δL|₁≈±0.5λ₀[1+(NΔn/πn_{eff})²]^{0.5}. A second minimum reflection region is located directly between a first side-lobe of the reflectance curve and a second side-lobe of the reflectance curve. The optical thickness detuning δL|₂ corresponding to the second minimum reflection can be estimated by δL|₂≈±λ₀[1+(NΔn/2πn_{eff})²]^{0.5}. N-pair detuned DBR that corresponds to the second minimum reflection can be equivalently regarded as a cascaded two segments of N/2-pair detuned DBR that corresponds to the first minimum reflection.

A reflectance curve of a regular DBR may have the optical stop-band substantially centered on the emission wavelength λ₀. Thus, the emission wavelength λ₀ may be aligned with zero on the x-axis.

A reflectance curve of detuned DBR or a reflectance curve derived from a combination of detuned DBRs may have a minimum reflection region (e.g., the first minimum reflection, the second minimum reflection, etc.) aligned with the emission wavelength λ₀. The optical thickness deviation may refer to the difference in the optical thickness of a detuned DBR at the emission wavelength λ₀, relative to its corresponding regular DBR which may have the optical stop-band substantially centered on the emission wavelength λ₀. Similarly, the phase deviation may refer to the difference in the phase change of a detuned DBR relative to its corresponding regular DBR, when an optical field of the emission wavelength λ₀ propagates therethrough. When the emission wavelength λ0 is located at a minimum reflection region of a reflectance curve, the detuned DBR or the combination of detuned DBRs induce, in an optical field of the emission wavelength propagating through the detuned DBR(s), a phase deviation substantially equal to π or an integer multiple of π. As a result, light penetrates through or leaks through the detuned DBR(s), effectively lengthening the optical cavity. In other words, the detuned DBR(s) elongate the effective cavity length by reducing reflection in the detuned DBR(s).

As indicated above, FIG. 3 is provided as an example. Other examples may differ from what is described with regard to FIG. 3.

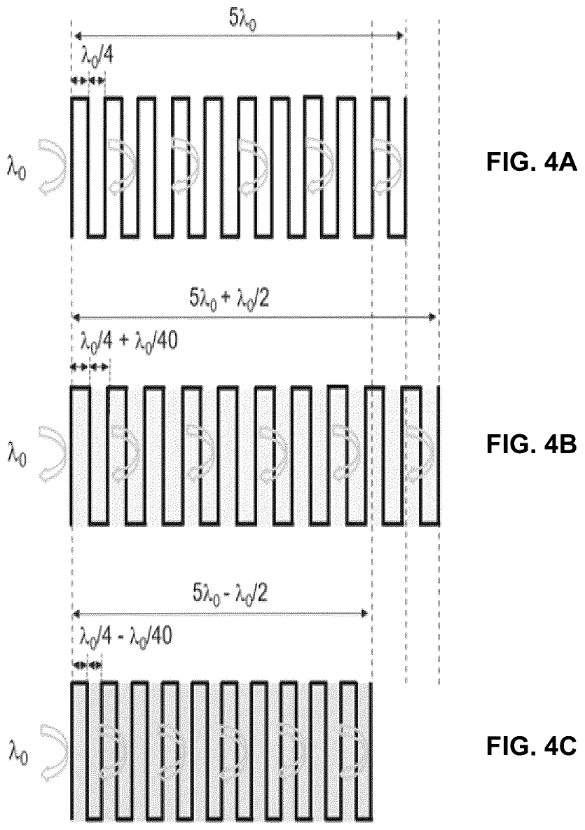

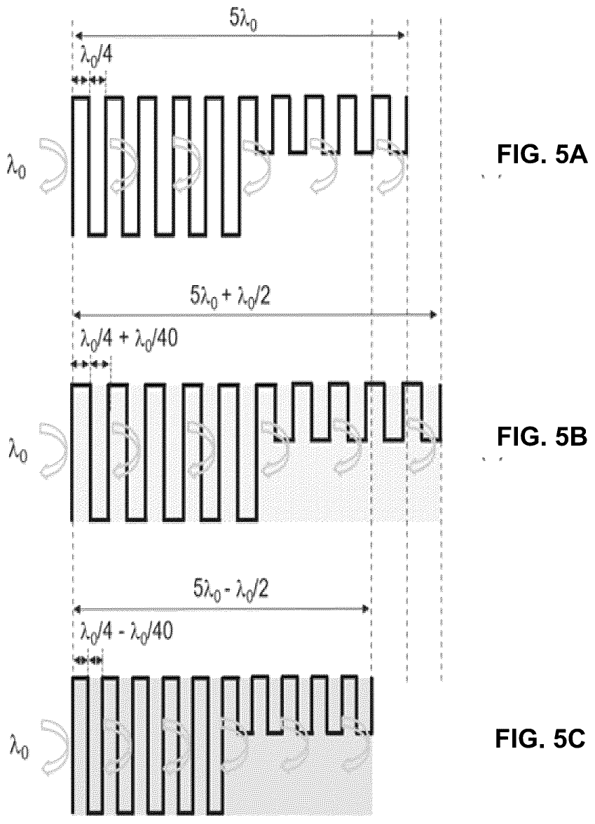

FIGS. 4A-4C show example detuning schematics of a 10-pair DBR with the optical thickness of 5λ₀ in FIGS. 4A, 5λ₀+λ₀/2 in FIG. 4B, and 5λ₀-λ₀/2 in FIG. 4C, where each half pair of DBR has the optical thickness of λ₀/4, λ₀/4+λ₀/40, and λ₀/4-λ₀/40, respectively.

The concept of a detuned DBR for optical penetration enhancement and reflection reduction is illustrated in FIGS. 4A-4C. A typical 10-pairs DBR, with a total optical thickness of 5λ₀, consists of alternate high refractive index and low refractive index quarter-wave (λ₀/4) layers, depicted in FIG. 4A. In comparison, FIGS. 4B and 4C show detuned DBRs with a half-wave (λ₀/2) deviation of optical thickness, which is evenly distributed through the 10-pairs DBR. Thus, in FIGS. 4B and 4C the half-wave optical thickness deviation is uniformly distributed in all layers. As a result, the detuned DBRs are still quarter-wave (λ_{d}/4) stacks corresponding to another wavelength λ_{d} instead of the emission wavelength λ₀. As shown in FIGS. 4B and 4C, the optical thickness of λ_{d}/4 stack is equal to λ₀/40 +λ₀/40 and λ₀/4-λ₀/40, respectively. For simplicity, FIGS. 4A-4C depicts only high and low refractive index layers but does not show the gradient layer, if present. Such detuned DBRs make the light of wavelength λ₀ mismatch from Bragg condition of maximum reflection on each half pair of DBR and thereby enhance optical penetration and reduce the light reflection. On the other hand, the accumulated half-wave deviation can still allow the light of wavelength λ₀ be in a resonance state. Accordingly, inserting a detuned DBR between an active region and regular DBRs, or within the regular DBRs can elongate an effective cavity length and narrow a beam divergence. Such detuned DBR structures may increase the effective cavity length more efficiently than merely using a lower contrast DBR.

The optical thickness is the product of geometrical thickness and optical refractive index n for a wavelength λ₀. For example, the optical thickness of a half-wave (λ₀/2) has a geometrical thickness of λ₀/2n, the light of wavelength λ₀ propagating in such a single medium layer experiences a phase shift of π.

As indicated above, FIGS. 4A-4C are provided as examples. Other examples may differ from what is described with regard to FIGS. 4A-4C.

FIGS. 5A-5C show example detuning schematics of a 10-pair DBR having two segments with different contrast, with the total optical thickness of 5λ₀ in FIG. 45A, 5λ₀+λ₀/2 in FIG. 5B, and 5λ₀-λ₀/2 in FIG. 5C, where each half pair of DBR has the optical thickness of λ₀/4, λ₀/4+λ₀/40, and λ₀/4-λ₀/40, respectively.

As indicated above, FIGS. 5A-5C are provided as examples. Other examples may differ from what is described with regard to FIGS. 5A-5C.

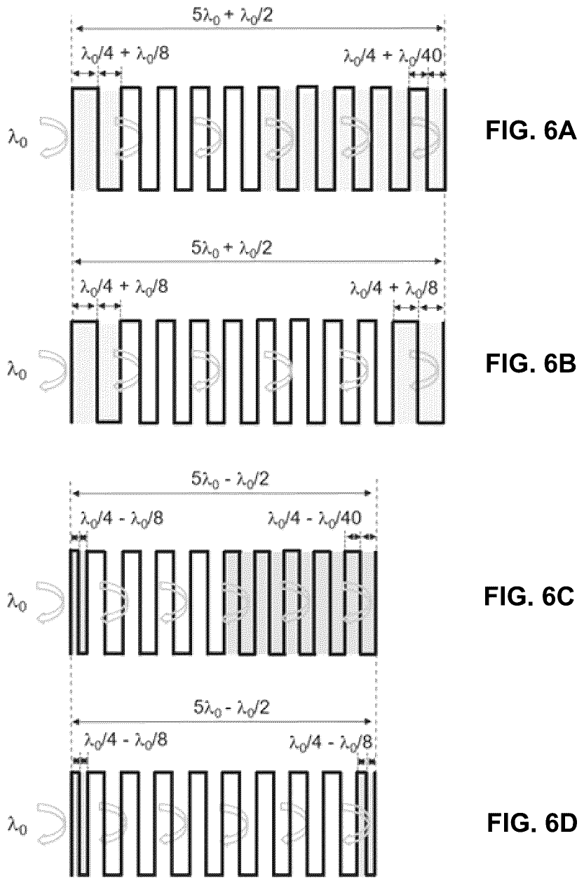

FIGS. 6A-6D show example detuning schematics of a 10-pair DBR with two detuned segments, each having λ₀/4 detuning. In FIG. 6A, a total optical thickness is 5λ₀+λ₀/2, where the half-pair optical thickness is λ₀/4+λ₀/8 for the first pair and λ₀/4+λ₀/40 for the last 5 pairs. In FIG. 6B, a total optical thickness is 5λ₀+λ₀/2, where the half-pair optical thickness is λ₀/4+λ₀/8 for both first pair and last pair. In FIG. 6C, a total optical thickness is 5λ₀-λ₀/2, where the half-pair optical thickness is λ₀/4-λ₀/8 for the first pair and λ₀/4-λ₀/40 for the last 5 pairs. In FIG. 6D, a total optical thickness is 5λ₀-λ₀/2, where the half pair optical thickness is λ₀/4-λ₀/8 for both first pair and last pair. The remaining DBRs are regular λ₀/4 stacks.

As indicated above, FIGS. 6A-6D are provided as examples. Other examples may differ from what is described with regard to FIGS. 6A-6D.

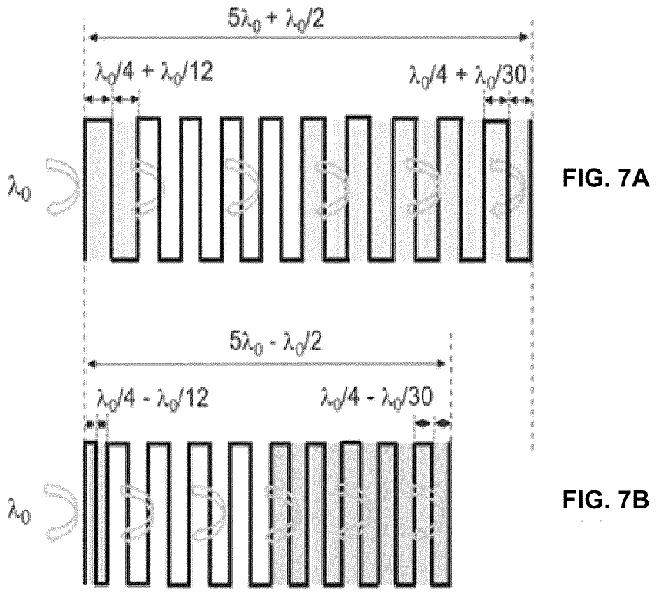

FIGS. 7A-7B show example detuning schematics of a 10-pair DBR with two detuned segments which have different detuning, wherein the first segment has λ₀/6 and the second has λ₀/3 detuning, respectively. In FIG. 7A, a total optical thickness is 5λ₀+λ₀/2, where the half-pair optical thickness is λ₀/4+λ₀/12 for the first pair and λ₀/4+λ₀/30 for the last 5 pairs. In FIG. 7B, a total optical thickness is 5λ₀-λ₀/2, where the half-pair optical thickness is λ₀/4-λ₀/12 for the first pair and λ₀/4-λ₀/30 for the last 5 pairs.

As indicated above, FIGS. 7A-7B are provided as examples. Other examples may differ from what is described with regard to FIGS. 7A-7B.

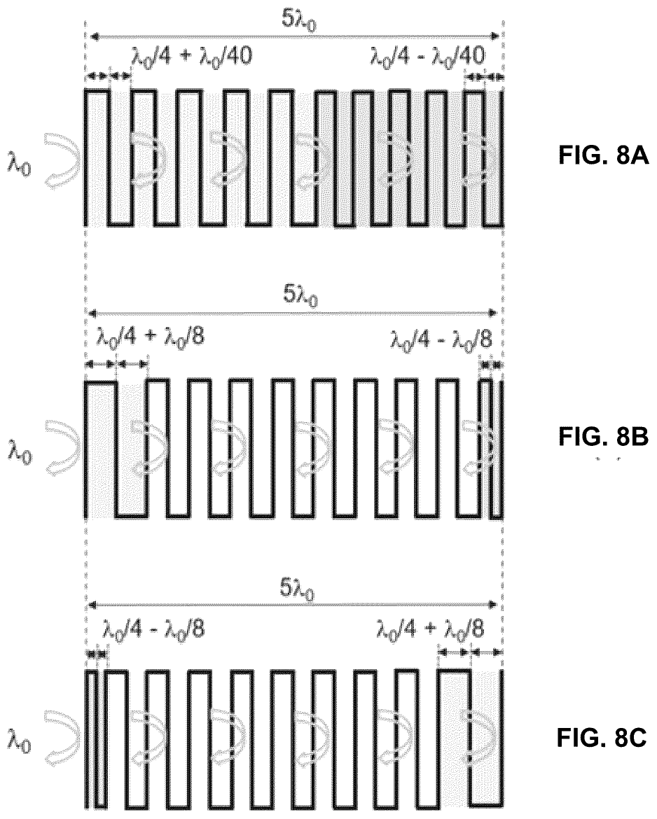

FIGS. 8A-8C show example detuning schematics of a 10-pair DBR having two segments of reverse detuning, one has λ₀/4 deviation, the other has −λ₀/4 deviation. That is, one segment detuning cancels out the other one, the total optical thickness is still 5λ₀. In FIG. 7A, a half-pair optical thickness is λ₀/4+λ₀/40 for the first 5 pairs and λ₀/4-λ₀/40 for the last 5 pairs. In FIG. 7B, a half-pair optical thickness is λ₀/4+λ₀/8 for the first pair and λ₀/4-λ₀/8 for the last pair. In FIG. 7C, a half pair optical thickness is λ₀/4-λ₀/8 for the first pair and λ₀/4+λ₀/8 for the last pair.

As indicated above, FIGS. 8A-8C are provided as examples. Other examples may differ from what is described with regard to FIGS. 8A-8C.

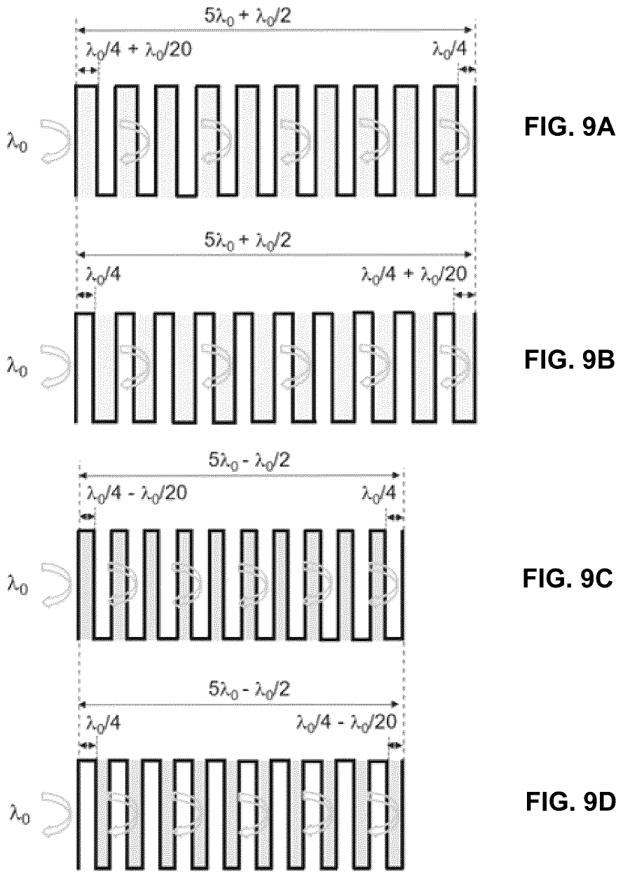

FIGS. 9A-9D show example detuning schematics of a 10-pair DBR with an optical thickness of λ₀/2 deviation. Here, the detuning is applied only in a high refractive index layer or a low refractive index layer for each DBR pair. FIG. 9A shows a total optical thickness of 5λ₀+λ₀/2 with detuning in a high refractive index layer. FIG. 9B shows a total optical thickness of 5λ₀+λ₀/2 with detuning in a low refractive index layer. FIG. 9C shows a total optical thickness of 5λ₀−λ₀/2 with detuning in a high refractive index layer. FIG. 9D shows a total optical thickness of 5λ₀−λ₀/2 with detuning in a low refractive index layer.

As indicated above, FIGS. 9A-9D are provided as examples. Other examples may differ from what is described with regard to FIGS. 9A-9D.

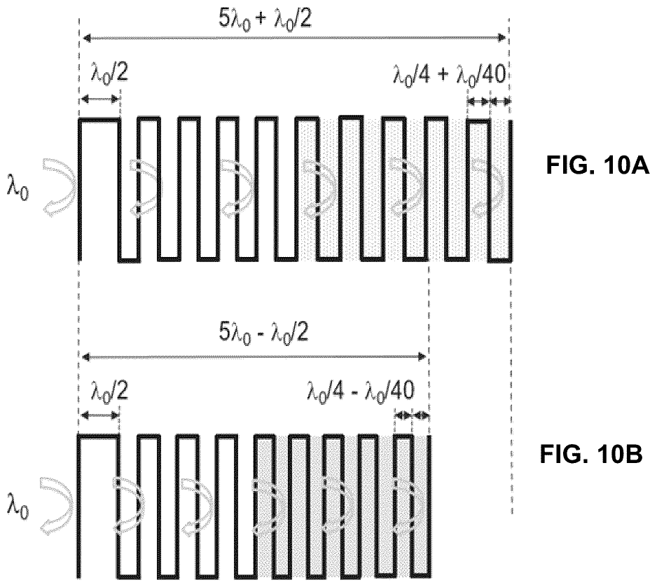

FIGS. 10A-10B show example detuning schematics of an optical thickness of λ₀/2 deviation relative to 10 pairs of DBR, including a λ₀/2 spacer and 5 pairs of λ₀/4-detuned DBR as well as a regular DBR between the λ₀/2 spacer and the detuned DBR. In FIG. 10A, a total optical thickness is 5λ₀+λ₀/2, wherein the λ₀/2 spacer is formed by inserting a λ₀/4 high-index layer into a left most DBR pair, and 5 pairs of λ₀/4-detuned DBR has a half-pair optical thickness of λ₀/4+λ₀/40. In FIG. 10B, a total optical thickness is 5λ₀-λ₀/2, wherein the λ₀/2 spacer is formed

by removing the λ₀/4 low-index layer from a left most DBR pair, and 5 pairs of λ₀/4-detuned DBR has half-pair optical thickness of λ₀/4-λ₀/40. The λ₀/2 spacer and the detuned DBR, in combination, induces a π phase deviation relative to 10 DBR pairs of a regular DBR. In other words, the λ₀/2 spacer and the detuned DBR, in combination, are configured to induce, in an optical field of the emission wavelength λ₀ propagating through the λ₀/2 spacer and the detuned DBR, a phase deviation substantially equal to π. Thus, the λ₀/2 spacer and the detuned DBR, in combination, are configured to induce a reflectance curve defining a pass-band or a minimum reflection region that is aligned with the emission wavelength λ₀.

As indicated above, FIGS. 10A-10B are provided as examples. Other examples may differ from what is described with regard to FIGS. 10A-10B.

A detuning DBR scheme may also be implemented by splitting the detuned DBRs into multiple different segments, and/or with different contrast, as shown in FIGS. 5A-5C, 6A-6D, and 7A-7B. Also, the optical thickness detuning distributed through the DBRs may not be even. In other words, the optical thickness detuning per DBR pair in different segments could be different as illustrated in FIGS. 6A and 6C. It may also only occur in the end pair of DBR as illustrated in FIGS. 6B and 6D, which has a deviation of λ₀/4 optical thickness each at both ends. Likewise, the last pair of DBR which has a deviation of λ₀/4 optical thickness may be located elsewhere within 10-pair DBRs. In the case of a one-pair detuned DBR with a deviation of λ₀/4, if all detuning occurs only in a high refractive index layer or a low refractive index layer, the one-pair detuned DBR becomes equivalent to inserting a λ₀/4 spacer layer (a uniform single medium) in a typical DBR. In such multiple segments of detuning, at least one detuned segment uses detuned DBRs, the other detuned segments may insert a spacer layer or multiple spacer layers. In FIGS. 6A-6D, the total λ₀/2 detuning is split evenly into two detuned segments, each having λ₀/4 detuning. The total λ₀/2 detuning could also be split in any proportion. For an example, FIGS. 7A-7B show schematics of a 10-pair DBR with two detuned segments, where a first segment has a λ₀/6 detuning and a second segment has a λ₀/3 detuning, respectively.

In some implementations, an accumulated detuning from multiple detuned segments is zero or close to zero. For instance, FIGS. 8A-8C show two segments with reversed detuning, where one segment has a λ₀/4 deviation, another segment has a −λ₀/4 deviation.

In some implementations, the detuning may not be evenly distributed through all DBR layers but applied only on part of DBR layers in each pair, such as a high refractive index layer, a low refractive index layer, a gradient layer, or a combination of part of these layers. FIGS. 9A-9D show example schematics of a 10-pair DBR with an optical thickness of λ₀/2 deviation. Here, the detuning is applied only in a high refractive index layer or a low refractive index layer for each DBR pair. Also, similar detuning may be applied on part of DBR pairs, for example, only detune an odd numbered pair, such as a 1^{st} pair, a 3^{rd} pair, a 5^{th} pair, and so on, or an even numbered pair, such as a 2^{nd} pair, a 4^{th} pair, a 6^{th} pair, and so on. Such a DBR detuning scheme of only detuning part of DBR layers or part of DBR pairs can be employed not only for λ₀/2 deviation as shown in FIGS. 9A-9D, but also for λ₀/4 deviation or other specific deviation. That is, the detuned segment with λ₀/4 deviation shown in FIGS. 5A-5C, 6A-6D, and 8A-8C, or other specific deviation in FIGS. 7A-7B may be in combination with the detuning in part of DBR layers or part of DBR pairs. To simplify, the DBR gradient layers which may be inserted between high and low refractive index layers are not depicted in the figures.

In the reflectance spectrum of a DBR example shown in FIG. 3, the first minimum reflection region corresponds to the optical thickness deviation which is not exactly a half-wave but has an offset, depending on the value of NΔn/n_{eff}. For the case of NΔn/n_{eff}~3, the optical thickness deviation is around 1.4 times of a half-wave length to satisfy the first minimum reflection condition as well as make the optical field propagating through the DBRs have a phase deviation substantially equal to π. Similarly, the optical thickness deviation is around 1.1 times of a wave length to satisfy the second minimum reflection condition. Only for small value of NΔn/n_{eff} (i.e., Δn<<n_{eff} and/or small N), the optical thickness deviation for the first minimum reflection δL|₁→±λ₀/2, and for the second minimum reflection δL|₂→±λ₀. For simplicity to illustrate the concept of detuned DBR, FIGS. 4-10 display a half-wave optical thickness deviation. As discussed above, an additional optical thickness detuning may need to be included to satisfy the minimum reflection condition, as well as make the optical field propagating through the DBRs have a phase deviation substantially equal to π.

In some implementations in which a detuned DBR is split into two segments, each segment may contribute to half of a total detuning (e.g., each segment contributing to about π/2 phase deviation), as shown in FIGS. 6A-6D, or another specific phase deviation, as shown in FIGS. 7A-7B. The evaluation of optical thickness detuning for such detuned segment could be obtained through numerical solution. However, for the detuned segment with a few pairs of low-contrast or one to two pairs of high-contrast DBR, the detuned optical thickness is approximated by multiplying λ₀/2π with the phase deviation in the design, the additional optical thickness detuning discussed above could be neglected.

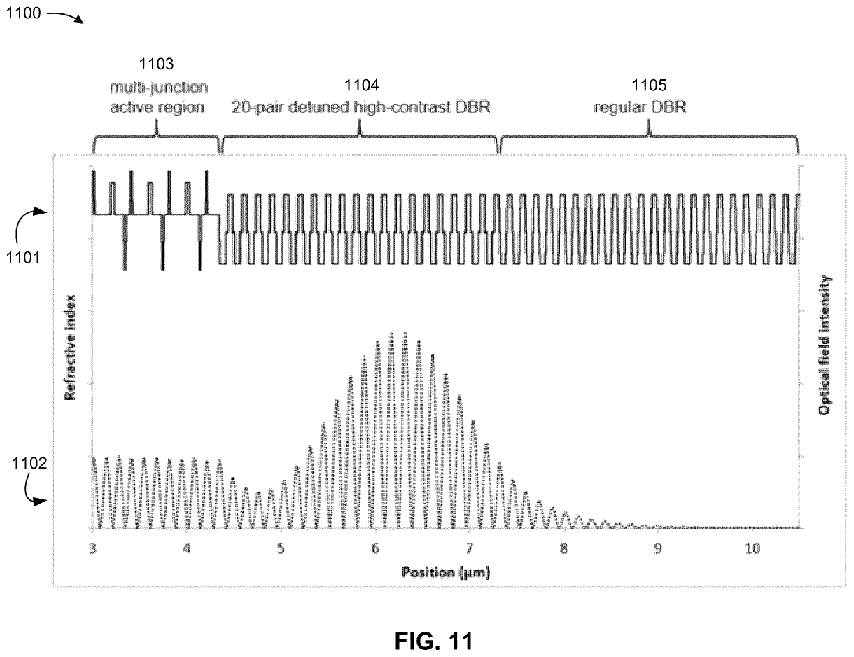

FIG. 11 shows a diagram 1100 including a refractive index curve 1101 and an optical field intensity curve 1102 of a multi-junction VCSEL emitter according to one or more implementations. The multi-junction VCSEL emitter may include a multi-junction active region 1103, a detuned DBR 1104, and a regular DBR 1105. The detuned DBR 1104 may be a 20-pair detuned high-contrast DBR inserted between the multi-junction active region 1103 and the regular DBR 1105. The multi-junction active region 1103 may correspond to the active region described in connection with FIG. 2A. The detuned DBR 1104 and the regular DBR 1105 may correspond to the detuned DBR 206 and the bottom DBR mirror 204 described in connection with FIG. 2A, respectively. Alternatively, the detuned DBR 1104 and the regular DBR 1105 may correspond to the second detuned DBR 236 and the top DBR mirror 228 described in connection with FIG. 2A. Light emitted at the emission wavelength from the multi-junction active region 1103 enters the detuned DBR 1104 and passes through the detuned DBR 1104 to the regular DBR 1105.

The detuned DBR 1104 may satisfy a 1^{st} minimum reflection condition. In other words, a reflectance curve of the detuned DBR 1104 may have a first minimum reflection region located directly between an optical stop-band and a first side-lobe of the reflectance curve. Accordingly, as shown by the optical field intensity curve 1102, the detuned DBR 1104 is configured to cause an envelope of an optical field peak intensity to exhibit a gradually-changing outline with a single peak over a length of the detuned DBR 1104. Moreover, the detuned DBR 1104 is configured to cause the optical field peak intensity over the length of the detuned DBR 1104 to firstly decrease based on light entering the detuned DBR 1104 from the multi-junction active region 1103, subsequently increase to form a peak as the light propagates through the detuned DBR 1104, and subsequently decrease as the light exists the detuned DBR 1104. The optical field peak intensity continues to decrease as the light enters the regular DBR 1105 from the detuned DBR 1104. The optical field peak intensity at some locations in the detuned DBR may be higher than those in active region. In some implementations, the doping level in the detuned DBR or a portion of the detuned DBR may be lower than the doping level in the regular DBR 1105.

In the example shown in FIG. 11, both the detuned DBR 1104 and the regular DBR 1105 have high-contrast Al_{0.1}Ga_{0.9}As/Al_{0.9}Ga_{0.1}As pairs. The regular DBR 1105 has λ₀/4 stacks. The detuned DBR 1104 has a total optical thickness deviation of about 1.4×λ₀/2, which is evenly distributed relative to a regular λ₀/4 stack DBR. Equivalently, the detuned DBR 1104 can be viewed as an about 1.07×λ₀/4 stack DBR. Such optical thickness detuning meets the requirement of the 1^{st} minimum reflection condition for the emission wavelength λ₀.

As indicated above, FIG. 11 is provided as an example. Other examples may differ from what is described with regard to FIG. 11.

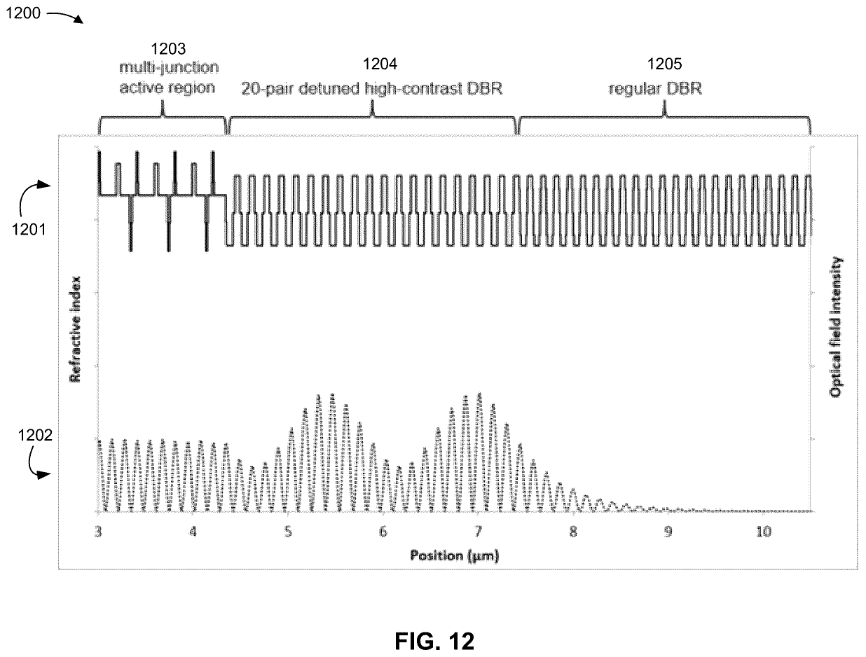

FIG. 12 shows a diagram 1200 including a refractive index curve 1201 and an optical field intensity curve 1202 of a multi-junction VCSEL emitter according to one or more implementations. The multi-junction VCSEL emitter may include a multi-junction active region 1203, a detuned DBR 1204, and a regular DBR 1205. The detuned DBR 1204 may be a 20-pair detuned high-contrast DBR inserted between the multi-junction active region 1203 and the regular DBR 1205. The multi-junction active region 1203 may correspond to the active region described in connection with FIG. 2A. The detuned DBR 1204 and the regular DBR 1205 may correspond to the detuned DBR 206 and the bottom DBR mirror 204 described in connection with FIG. 2A, respectively. Alternatively, the detuned DBR 1204 and the regular DBR 1205 may correspond to the second detuned DBR 236 and the top DBR mirror 228 described in connection with FIG. 2A. Light emitted at the emission wavelength from the multi-junction active region 1203 enters the detuned DBR 1204 and passes through the detuned DBR 1204 to the regular DBR 1205.

The detuned DBR 1204 may satisfy a 2^{nd} minimum reflection condition. In other words, a reflectance curve of the detuned DBR 1204 may have a second minimum reflection region located directly between a first side-lobe of the reflectance curve and a second side-lobe of the reflectance curve. Accordingly, as shown by the optical field intensity curve 1202, the detuned DBR 1204 is configured to cause an envelope of an optical field peak intensity to exhibit a gradually-changing outline with two peaks over a length of the detuned DBR 1204. Moreover, the detuned DBR 1204 is configured to cause the optical field peak intensity over the length of the detuned DBR 1204 to firstly decrease based on light entering the detuned DBR 1204 from the multi-junction active region 1203, subsequently increase to form a first peak as the light propagates through the detuned DBR 1204, subsequently decrease and increase to form a second peak as the light continues to propagate through the detuned DBR 1204, and subsequently decrease as the light exists the detuned DBR 1204. The optical field peak intensity continues to decrease as the light enters the regular DBR 1205 from the detuned DBR 1204. The optical field peak intensity at some locations in the detuned DBR may be higher than those in active region. In some implementations, the doping level in the detuned DBR or a portion of the detuned DBR may be lower than the doping level in the regular DBR 1205.

In the example shown in FIG. 12, both the detuned DBR 1204 and the regular DBR 1205 have high-contrast Al_{0.1}Ga_{0.9}As/Al_{0.9}Ga_{0.1}As pairs. The detuned DBR 1204 has a total optical thickness deviation of about 1.1×λ₀, which is evenly distributed relative to a regular λ₀/4 stack DBR. Equivalently, the detuned DBR 1204 can be viewed as a 1.11×λ₀/4 stack DBR. Such optical thickness detuning meets the requirement for the 2^{nd} minimum reflection. The simulated optical field shows double peaks but with much less intensity depicted in FIG. 12, compared to the 1^{st} minimum reflection depicted in FIG. 11. That indicates the effect of elongated cavity employing the detuned DBR 1204 with the 2^{nd} minimum reflection condition is inferior to the one with a 1^{st} minimum reflection condition. That is to say, the detuned DBR 1204 provides has a shorter effective cavity length elongation than the detuned DBR 1104. Alternatively, the detuned DBR 1204, with 20 DBR pairs, can be equivalently regarded as a cascaded two segments of 10-pair detuned DBR that corresponds to the 1^{st} minimum reflection. Here, the optical thickness deviation of each segment is 1.1×λ₀/2, which is evenly distributed in all DBR layers, thus forming a 1.11×λ₀/4 stack DBR.

As indicated above, FIG. 12 is provided as an example. Other examples may differ from what is described with regard to FIG. 12.

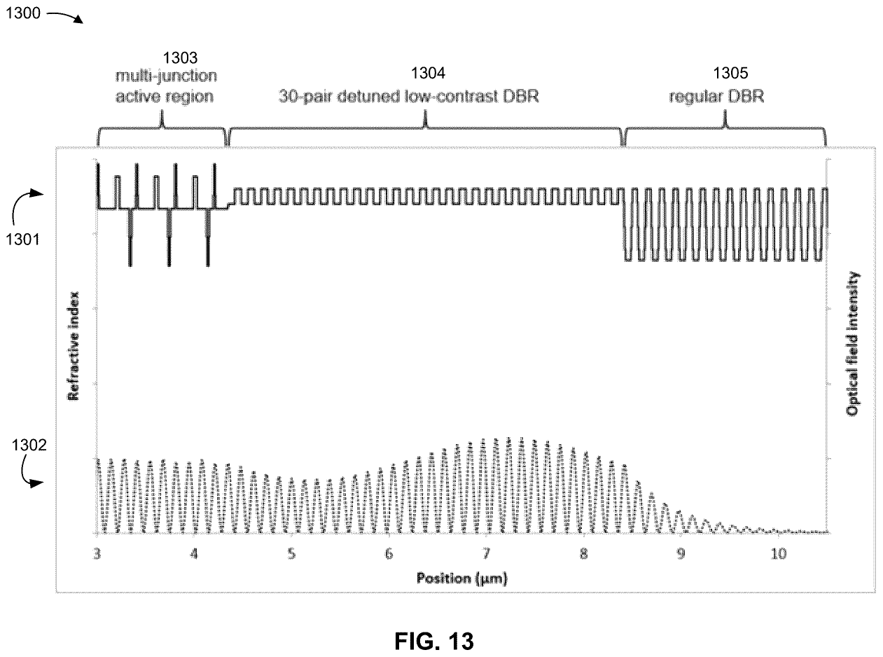

FIG. 13 shows a diagram 1300 including a refractive index curve 1301 and an optical field intensity curve 1302 of a multi-junction VCSEL emitter according to one or more implementations. The multi-junction VCSEL emitter may include a multi-junction active region 1303, a detuned DBR 1304, and a regular DBR 1305. The detuned DBR 1304 may be a 30-pair detuned low-contrast DBR inserted between the multi-junction active region 1303 and the regular DBR 1305. The multi-junction active region 1303 may correspond to the active region described in connection with FIG. 2A. The detuned DBR 1304 and the regular DBR 1305 may correspond to the detuned DBR 206 and the bottom DBR mirror 204 described in connection with FIG. 2A, respectively. Alternatively, the detuned DBR 1304 and the regular DBR 1305 may correspond to the second detuned DBR 236 and the top DBR mirror 228 described in connection with FIG. 2A. Light emitted at the emission wavelength from the multi-junction active region 1303 enters the detuned DBR 1304 and passes through the detuned DBR 1304 to the regular DBR 1305.

The detuned DBR 1304 may satisfy a 1^{st} minimum reflection condition. In other words, a reflectance curve of the detuned DBR 1304 may have a first minimum reflection region located directly between an optical stop-band and a first side-lobe of the reflectance curve. Accordingly, as shown by the optical field intensity curve 1302, the detuned DBR 1304 is configured to cause an envelope of an optical field peak intensity to exhibit a gradually-changing outline with a single peak over a length of the detuned DBR 1304. Moreover, the detuned DBR 1304 is configured to cause the optical field peak intensity over the length of the detuned DBR 1304 to firstly decrease based on light entering the detuned DBR 1304 from the multi-junction active region 1303, subsequently increase to form a peak as the light propagates through the detuned DBR 1304, and subsequently decrease as the light exists the detuned DBR 1304. The optical field peak intensity continues to decrease as the light enters the regular DBR 1305 from the detuned DBR 1304. The optical field peak intensity at some locations in the detuned DBR may be higher than those in active region. In some implementations, the doping level in the detuned DBR or a portion of the detuned DBR may be lower than the doping level in the regular DBR 1305.

In the example shown in FIG. 13, the detuned DBR 1304 has low-contrast Al_{0.1}Ga_{0.9}As/Al_{0.25}Ga_{0.75}As pairs. The detuned DBR 1304 has a total optical thickness deviation of about 1.05×λ₀/2 which is evenly distributed relative to a regular λ₀/4 stack DBR. Equivalently, the detuned DBR 1304 can be viewed as an about 1.035×λ₀/4 stack DBR. Such optical thickness detuning meets the requirement of the 1^{st} minimum reflection condition for the emission wavelength λ₀.

As indicated above, FIG. 13 is provided as an example. Other examples may differ from what is described with regard to FIG. 13.

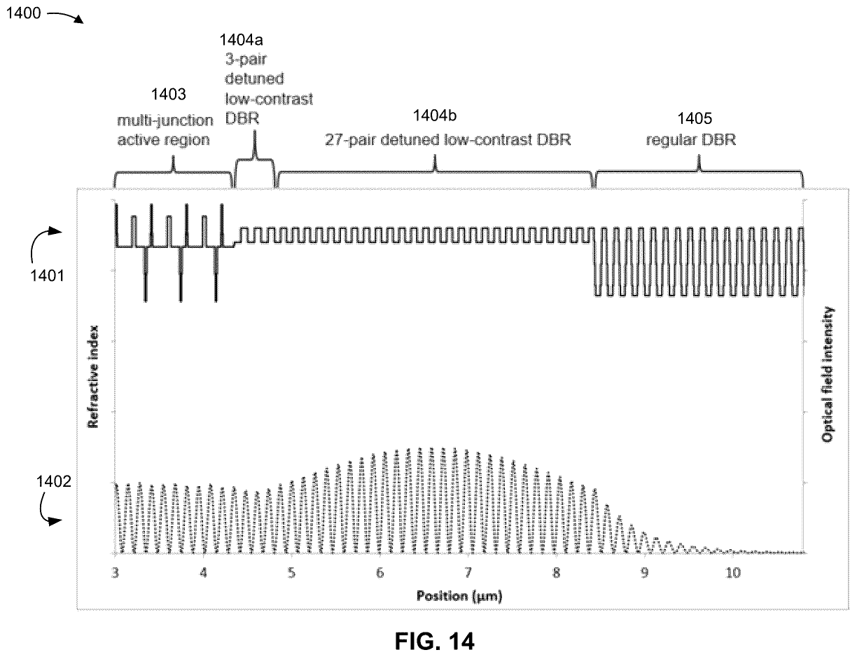

FIG. 14 shows a diagram 1400 including a refractive index curve 1401 and an optical field intensity curve 1402 of a multi-junction VCSEL emitter according to one or more implementations. The multi-junction VCSEL emitter may include a multi-junction active region 1403, a first detuned DBR 1404a, a second detuned DBR 1404b, and a regular DBR 1405. The first detuned DBR 1404a may be a 3-pair detuned low-contrast DBR and the second detuned DBR 1404b may be a 27-pair detuned low-contrast DBR. The multi-junction active region 1403 may correspond to the active region described in connection with FIG. 2B. The first detuned DBR 1404a, a second detuned DBR 1404b, and a regular DBR 1405 may correspond to the first detuned DBR 238, the second detuned DBR 240, and the bottom DBR mirror 204 described in connection with FIG. 2B, respectively. Light emitted at the emission wavelength from the multi-junction active region 1403 enters the first detuned DBR 1404a, passes through the first detuned DBR 1404a, enters the second detuned DBR 1404b, and passes through the second detuned DBR 1404b to the regular DBR 1405. Thus, the first detuned DBR 1404a is arranged closer to the multi-junction active region 1403 than the second detuned DBR 1404b.

The first detuned DBR 1404a and the second detuned DBR 1404b, in combination, may satisfy the 1^{st} minimum reflection condition for the emission wavelength λ₀. For example, first detuned DBR 1404a and the second detuned DBR 1404b, in combination, are configured to cause an optical field peak intensity over a combined length of the first detuned DBR 1404a and the second detuned DBR 1404b to firstly decrease based on light entering the first detuned DBR 1404a from the multi-junction active region 1403, subsequently increase to form a peak as the light propagates through the second detuned DBR 1404b, and subsequently decrease as the light exists the second detuned DBR 1404b. The optical field peak intensity continues to decrease as the light enters the regular DBR 1405 from the second detuned DBR 1404b. The optical field peak intensity at some locations in the detuned DBR may be higher than those in active region. In some implementations, the doping level in the detuned DBR or a portion of the detuned DBR may be lower than the doping level in the regular DBR 1405.

In the example shown in FIG. 14, the first detuned DBR 1404a has low-contrast Al_{0.1}Ga_{0.9}As/Al_{0.25}Ga_{0.75}As pairs and the second detuned DBR 1404b has low-contrast Al_{0.1}Ga_{0.9}As/Al_{0.25}Ga_{0.75}As pairs. The first detuned DBR 1404a has optical thickness deviation of about λ₀/4, evenly distributed relative to a regular low-contrast λ₀/4 stack DBR, contributing about π/2 phase deviation for optical field of the wavelength λ₀. The second detuned DBR 1404b has a total optical thickness deviation of about 1.3×λ₀/4, evenly distributed relative to a regular low-contrast λ₀/4 stack DBR, contributing about π/2 phase deviation for optical field of the wavelength λ₀. Thus, the combination of the first detuned DBR 1404a and the second detuned DBR 1404b satisfies the 1^{st} minimum reflection condition for the emission wavelength λ₀.

As indicated above, FIG. 14 is provided as an example. Other examples may differ from what is described with regard to FIG. 14.

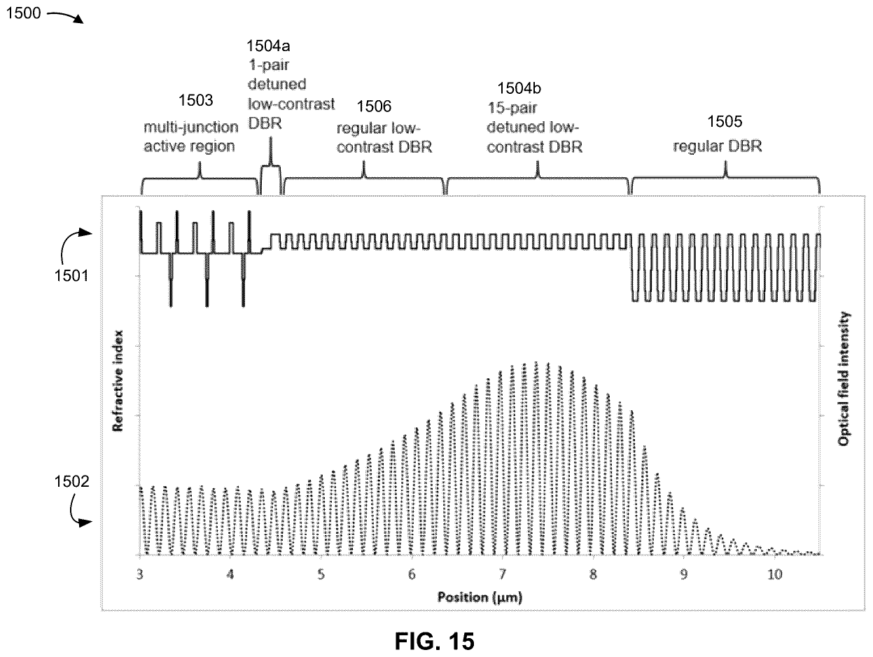

FIG. 15 shows a diagram 1500 including a refractive index curve 1501 and an optical field intensity curve 1502 of a multi-junction VCSEL emitter according to one or more implementations. The multi-junction VCSEL emitter may include a multi-junction active region 1503, a first detuned DBR 1504a, a second detuned DBR 1504b, a regular DBR 1505, and a regular DBR 1506. The regular DBR 1506 may be arranged between the first detuned DBR 1504a and the second detuned DBR 1504b. The first detuned DBR 1504a, the second detuned DBR 1504b, and the regular DBR 1506 may be arranged between multi-junction active region 1503 and the regular DBR 1505. The regular DBR 1505 may correspond to a bottom DBR mirror (e.g., bottom DBR mirror 204) or a top DBR mirror (e.g., top DBR mirror 228). The first detuned DBR 1504a may be a 1-pair detuned low-contrast DBR and the second detuned DBR 1504b may be a 15-pair detuned low-contrast DBR. Additionally, the regular DBR 1506 may be a low-contrast DBR, whereas the regular DBR 1505 may be a high-contrast DBR.

In some implementations, the first detuned DBR 1504a and the second detuned DBR 1504b may correspond to the first detuned DBR 238 and the second detuned DBR 240 described in connection with FIG. 2B, respectively. The regular DBR 1506 may correspond to the intermediate DBR mirror 242 described in connection with FIG. 2B. The multi-junction active region 1503 may correspond to the active region described in connection with FIG. 2B. Light emitted at the emission wavelength from the multi-junction active region 1503 enters and passes through the first detuned DBR 1504a, enters and passes through the regular DBR 1506, enters and passes through the second detuned DBR 1504b to the regular DBR 1505. Thus, the first detuned DBR 1504a is arranged closer to the multi-junction active region 1503 than the second detuned DBR 1504b.

The first detuned DBR 1504a and the second detuned DBR 1504b, in combination, may satisfy the 1^{st} minimum reflection condition for the emission wavelength λ₀. For example, first detuned DBR 1504a and the second detuned DBR 1504b, in combination, are configured to cause an optical field peak intensity over a combined length of the first detuned DBR 1504a and the second detuned DBR 1504b to firstly decrease based on light entering the first detuned DBR 1504a from the multi-junction active region 1503, subsequently increase as the light passes through the regular DBR 1506, subsequently increase to form a peak as the light propagates through the second detuned DBR 1504b, and subsequently decrease as the light exists the second detuned DBR 1504b. The optical field peak intensity continues to decrease as the light enters the regular DBR 1505 from the second detuned DBR 1504b. The optical field peak intensity at some locations in the detuned DBR may be higher than those in active region. In some implementations, the doping level in the detuned DBR or a portion of the detuned DBR may be lower than the doping level in the regular DBR 1505.

In the example shown in FIG. 15, the first detuned DBR 1504a has a low-contrast Al_{0.1}Ga_{0.9}As/Al_{0.25}Ga_{0.75}As pair and the second detuned DBR 1504b has low-contrast Al_{0.1}Ga_{0.9}As/Al_{0.25}Ga_{0.75}As pairs. Additionally, the regular DBR 1506 has low-contrast Al_{0.1}Ga_{0.9}As/Al_{0.25}Ga_{0.75}As pairs. The regular DBR 1506 may have 14 DBR pairs. The first detuned DBR 1504a has a total optical thickness deviation of λ₀/4, evenly distributed relative to a regular low-contrast λ₀/4 stack DBR, contributing to about a π/2 phase deviation for an optical field. The second detuned DBR 1504b has a total optical thickness deviation of about 1.14×λ₀/4, evenly distributed relative to a regular λ₀/4 stack DBR, contributing about π/2 phase deviation for the optical field. The combination of the first detuned DBR 1504a and the second detuned DBR 1504b form a reflectance curve that satisfies the 1^{st} minimum reflection condition for the emission wavelength λ₀.

By comparing the optical fields in FIGS. 14 and 15, FIG. 15 demonstrates that a two-segment detuned DBR with a regular DBR inserted between the two detuned DBR segments has stronger optical penetration, and therefore a longer effective cavity than the arrangement shown in FIG. 14. Thus, the arrangement shown in FIG. 15 may have a more narrow beam divergence when compared to the arrangement shown in FIG. 14.

As indicated above, FIG. 15 is provided as an example. Other examples may differ from what is described with regard to FIG. 15.

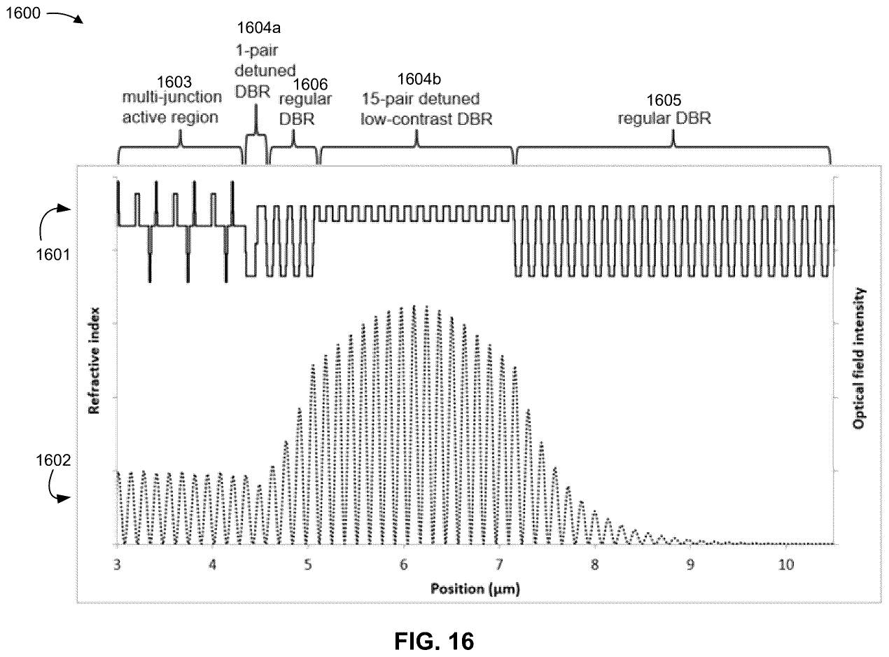

FIG. 16 shows a diagram 1600 including a refractive index curve 1601 and an optical field intensity curve 1602 of a multi-junction VCSEL emitter according to one or more implementations. The multi-junction VCSEL emitter may include a multi-junction active region 1603, a first detuned DBR 1604a, a second detuned DBR 1604b, a regular DBR 1605, and a regular DBR 1606. The regular DBR 1606 may be arranged between the first detuned DBR 1604a and the second detuned DBR 1604b. The first detuned DBR 1604a, the second detuned DBR 1604b, and the regular DBR 1606 may be arranged between multi-junction active region 1603 and the regular DBR 1605. The regular DBR 1605 may correspond to a bottom DBR mirror (e.g., bottom DBR mirror 204) or a top DBR mirror (e.g., top DBR mirror 228). The first detuned DBR 1604a may be a 1-pair detuned high-contrast DBR and the second detuned DBR 1604b may be a 15-pair detuned low-contrast DBR. Additionally, the regular DBR 1605 and the regular DBR 1606 may be a high-contrast DBRs.

In some implementations, the first detuned DBR 1604a and the second detuned DBR 1604b may correspond to the first detuned DBR 238 and the second detuned DBR 240 described in connection with FIG. 2B, respectively. The regular DBR 1606 may correspond to the intermediate DBR mirror 242 described in connection with FIG. 2B. The multi-junction active region 1603 may correspond to the active region described in connection with FIG. 2B. Light emitted at the emission wavelength from the multi-junction active region 1603 enters and passes through the first detuned DBR 1604a, enters and passes through the regular DBR 1606, enters and passes through the second detuned DBR 1604b to the regular DBR 1605. Thus, the first detuned DBR 1604a is arranged closer to the multi-junction active region 1603 than the second detuned DBR 1604b.

The first detuned DBR 1604a and the second detuned DBR 1604b, in combination, may satisfy the 1^{st} minimum reflection condition for the emission wavelength λ₀. For example, first detuned DBR 1604a and the second detuned DBR 1604b, in combination, are configured to cause an optical field peak intensity over a combined length of the first detuned DBR 1604a and the second detuned DBR 1604b to firstly decrease based on light entering the first detuned DBR 1604a from the multi-junction active region 1603, subsequently increase as the light passes through the regular DBR 1606, subsequently increase to form a peak as the light propagates through the second detuned DBR 1604b, and subsequently decrease as the light exists the second detuned DBR 1604b. The optical field peak intensity continues to decrease as the light enters the regular DBR 1605 from the second detuned DBR 1604b. The optical field peak intensity at some locations in the detuned DBR may be higher than those in active region. In some implementations, the doping level in the detuned DBR or a portion of the detuned DBR may be lower than the doping level in the regular DBR 1605.

In the example shown in FIG. 16, the first detuned DBR 1604a has a high-contrast Al_{0.1}Ga_{0.9}As/Al_{0.9}Ga_{0.1}As pair and the second detuned DBR 1604b has low-contrast Al_{0.1}Ga_{0.9}As/Al_{0.25}Ga_{0.75}As pairs. Additionally, the regular DBR 1606 has high-contrast Al_{0.1}Ga_{0.9}As/Al_{0.9}Ga_{0.1}As. The first detuned DBR 1604a has an optical thickness deviation of λ₀/4, evenly distributed relative to a regular λ₀/4 stack DBR, contributing about π/2 phase deviation for optical field. The second detuned DBR 1604b has a total optical thickness deviation of about 1.14×λ₀/4, evenly distributed relative to a regular low-contrast λ₀/4 stack DBR, contributing about π/2 phase deviation for the optical field. The combination of the first detuned DBR 1604a and the second detuned DBR 1604b form a reflectance curve that satisfies the 1^{st} minimum reflection condition for the emission wavelength λ₀.

As indicated above, FIG. 16 is provided as an example. Other examples may differ from what is described with regard to FIG. 16.

The following provides further Aspects of the present disclosure:
A detuned DBR has distributed detuning in terms of either optical thickness deviation or phase deviation, achieved through changing DBR layer geometrical thickness, or refractive index (i.e., using different material and/or changing material composition), or both thickness and refractive index.

The values of optical thickness deviation calculated in different examples in the context may not be exactly accurate to satisfy the minimum reflection conditions. In practice, it may not have to be exact. A detuned DBR may have under or over detuning, with optical thickness deviation off the minimum reflection conditions. Such non-perfect detuning can still reduce the reflection to some extent but may induce the resonant wavelength off the target wavelength λ₀. For a practical design, it may be acceptable for such non-perfect detuning which causing λ₀ shifted up to about ±5 nm in the wavelength range of 800 to 1100 nm, or ±10 nm in the wavelength range of 1100 to 1600 nm.

The detuned DBR may be based on λ₀/4, 3λ₀/4, 5λ₀/4 . . . stack DBR, (e.g., odd integer of λ₀/4 stack).

The detuned DBR may have detuning in high refractive index layer, or low refractive index layer, and/or gradient layers, including all combinations thereof.

The structure may have an additional spacer or regular DBRs (either high-contrast or low-contrast DBR, or both) between an active region and detuned DBRs.

Like standard VCSELs where oxidation and tunnel-junction layers can be part of regular DBRs, oxidation and tunnel-junction layers could be part of detuned DBRs.

In the scheme using multiple segments of detuning such as FIGS. 2, 5, 6, 7, 8, 14, 15, 16, at least one detuned segment has detuned DBRs, the other detuned segments may use a spacer layer or multiple spacer layers. It is noted that a spacer layer with the optical thickness deviation of λ₀/4 or an odd multiplier of λ₀/4, a uniform single layer placed in the front, the end, or the middle of DBRs, is merely a special case.

The detuned DBRs may be placed near to or close to the active region in either a bottom DBR side and/or a top DBR side.

The multi-junction VCSELs may have one, two, three, four, five, six, seven, or more junctions.

A VCSEL device may be a VCSEL single emitter or a VCSEL emitter array. The VCSEL device may be a top emitting VCSEL or a bottom emitting VCSEL. Oxide-confined VCSELs may have one, two, or more oxide layers at either a p-side or an n-side. The use of an optical aperture (OA) layer in the VCSELs for current and mode confinement is optional and may be replaced or combined with different approaches such as implant passivation, mesa, moat trench isolation, or buried tunnel junction (TJ).

From a perspective of device polarity, the VCSEL device with detuned DBRs may be a standard PIN type emitter, or an NIPN emitter for common-anode applications, where, “I” denotes the active region or cavity, “P” and “N” denotes p-type and n-type doped semiconductors, respectively. The detuned DBR may be placed on a bottom side and/or a top side. Also, there may be additional tunnel-junctions to change carrier polarity for different type contacts and/or replacing part of p-type materials for reducing optical absorption.

Some implementations described herein may be applied to any light emitter that uses a DBR or distributed-feedback (DFB), or other similar light emitters that provide distributed reflection as an optical reflector or as part of an optical reflector.

The following provides an overview of some Aspects of the present disclosure:
Aspect 1: An emitter, comprising: a bottom DBR mirror, the bottom DBR mirror characterized by a first reflectance curve that defines a first optical stop-band having a first center wavelength substantially aligned with an emission wavelength; a top DBR mirror arranged on the bottom DBR mirror, the top DBR mirror characterized by a second reflectance curve that defines a second optical stop-band having a second center wavelength substantially aligned with the emission wavelength; an active region formed by one or more active layers comprising one or more junctions, each junction including one or more quantum wells, wherein the active region is configured to generate laser light at the emission wavelength, and wherein the active region is arranged between the top DBR mirror and the bottom DBR mirror; a first detuned DBR arranged between the bottom DBR mirror and the active region or between the top DBR mirror and the active region, the first detuned DBR characterized by a third reflectance curve that defines a third optical stop-band and a minimum reflection region, wherein the third optical stop-band is offset from the emission wavelength, and wherein the minimum reflection region is aligned with the emission wavelength; and an optical output arranged over the top DBR mirror, wherein the emitter is configured to emit the laser light via the optical output.
Aspect 2: The emitter of Aspect 1, wherein the minimum reflection region is a first minimum reflection region located directly between the third optical stop-band and a first side-lobe of the third reflectance curve.
Aspect 3: The emitter of Aspect 2, wherein the bottom DBR mirror, the top DBR mirror, the first detuned DBR, and the active region define an optical cavity of the emitter, and wherein the first detuned DBR is configured to cause an envelope of an optical field peak intensity to exhibit a gradually-changing outline with a single peak over a length of the first detuned DBR.
Aspect 4: The emitter of any of Aspects 1-3, wherein the minimum reflection region is a second minimum reflection region located directly between a first side-lobe of the third reflectance curve and a second side-lobe of the third reflectance curve.
Aspect 5: The emitter of Aspect 4, wherein the bottom DBR mirror, the top DBR mirror, the first detuned DBR, and the active region define an optical cavity of the emitter, and wherein the first detuned DBR is configured to cause an envelope of an optical field peak intensity to exhibit a gradually-changing outline with two peaks over a length of the first detuned DBR.
Aspect 6: The emitter of any of Aspects 1-5, wherein the bottom DBR mirror, the top DBR mirror, and the active region define an optical cavity of the emitter, and wherein the first detuned DBR is configured to increase an effective cavity length of the optical cavity.
Aspect 7: The emitter of any of Aspects 1-6, wherein the first detuned DBR is configured to cause an optical field peak intensity over a length of the first detuned DBR to firstly decrease based on light entering the first detuned DBR from the active region, subsequently increase to form at least one peak as the light propagates through the first detuned DBR, and subsequently decrease as the light exists the first detuned DBR.
Aspect 8: The emitter of any of Aspects 1-7, wherein the first detuned DBR has an optical thickness deviation that is offset from a half-wavelength integer of the emission wavelength.
Aspect 9: The emitter of any of Aspects 1-8, wherein the first detuned DBR comprises a plurality of high and low refractive index layer pairs, and wherein the first detuned DBR has a total optical thickness that is evenly distributed among the plurality of high and low refractive index layer pairs.
Aspect 10: The emitter of any of Aspects 1-9, wherein the first detuned DBR comprises a plurality of high and low refractive index layer pairs, and wherein the first detuned DBR has a total optical thickness that is unevenly distributed among the plurality of high and low refractive index layer pairs.
Aspect 11: The emitter of any of Aspects 1-10, wherein the first detuned DBR induces, in an optical field of the emission wavelength propagating through the first detuned DBR, a phase deviation substantially equal to π or substantially equal to an integer of π.
Aspect 12: The emitter of any of Aspects 1-11, further comprising: a second detuned DBR arranged between the top DBR mirror and the active region, the second detuned DBR characterized by a fourth reflectance curve that defines a fourth optical stop-band and a further minimum reflection region, wherein the fourth optical stop-band is offset from the emission wavelength, and wherein the further minimum reflection region of the second detuned DBR is aligned with the emission wavelength, wherein the first detuned DBR is arranged between the bottom DBR mirror and the active region.
Aspect 13: The emitter of Aspect 12, wherein the first detuned DBR and the second detuned DBR are configured to increase an effective cavity length of the emitter.
Aspect 14: An emitter, comprising: a bottom DBR mirror, the bottom DBR mirror characterized by a first reflectance curve that defines a first optical stop-band having a first center wavelength substantially aligned with an emission wavelength; a top DBR mirror arranged on the bottom DBR mirror, the top DBR mirror characterized by a second reflectance curve that defines a second optical stop-band having a second center wavelength substantially aligned with the emission wavelength; an active region formed by one or more active layers comprising one or more junctions, each junction including one or more quantum wells, wherein the active region is configured to generate laser light at the emission wavelength, and wherein the active region is arranged between the top DBR mirror and the bottom DBR mirror; a first detuned DBR arranged between the bottom DBR mirror and the active region or between the top DBR mirror and the active region, wherein the bottom DBR mirror, the top DBR mirror, the first detuned DBR, and the active region define an optical cavity of the emitter, and wherein the first detuned DBR is configured to increase an effective cavity length of the optical cavity; and an optical output arranged over the top DBR mirror, wherein the emitter is configured to emit the laser light via the optical output.
Aspect 15: The emitter of Aspect 14, further comprising: a spacer arranged proximate to the first detuned DBR, wherein the first detuned DBR and the spacer, in combination, are configured to induce a reflectance curve defining a pass-band or a minimum reflection region that is aligned with the emission wavelength, and/or wherein the first detuned DBR and the spacer, in combination, are configured to induce, in an optical field of the emission wavelength propagating through the spacer and the first detuned DBR, a phase deviation substantially equal to π or substantially equal to an integer of π.
Aspect 16: The emitter of any of Aspects 14, wherein the first detuned DBR is characterized by a third reflectance curve that defines a pass-band aligned with the emission wavelength.
Aspect 17: The emitter of Aspect 16, wherein the pass-band is a first minimum reflection region located directly between an optical stop-band of the third reflectance curve and a first side-lobe of the third reflectance curve, or wherein the pass-band is a second minimum reflection region located directly between the first side-lobe of the third reflectance curve and a second side-lobe of the third reflectance curve.
Aspect 18: An emitter, comprising: a bottom DBR mirror, the bottom DBR mirror characterized by a first reflectance curve that defines a first optical stop-band having a first center wavelength substantially aligned with an emission wavelength; a top DBR mirror arranged on the bottom DBR mirror, the top DBR mirror characterized by a second reflectance curve that defines a second optical stop-band having a second center wavelength substantially aligned with the emission wavelength; an active region formed by one or more active layers comprising one or more junctions, each junction including one or more quantum wells, wherein the active region is configured to generate laser light at the emission wavelength, and wherein the active region is arranged between the top DBR mirror and the bottom DBR mirror; a first detuned DBR arranged between the bottom DBR mirror and the active region or between the top DBR mirror and the active region, the first detuned DBR characterized by a third reflectance curve; a second detuned DBR arranged between the bottom DBR mirror and the active region or between the top DBR mirror and the active region, the second detuned DBR characterized by a fourth reflectance curve, wherein the first detuned DBR and the second detuned DBR, in combination, are configured to induce, in an optical field of the emission wavelength propagating through the first detuned DBR and the second detuned DBR, a phase deviation substantially equal to π or substantially equal to an integer of π; and an optical output arranged over the top DBR mirror, wherein the emitter is configured to emit the laser light via the optical output.
Aspect 19: The emitter of Aspect 18, wherein the first detuned DBR is configured to induce, in the optical field of the emission wavelength propagating through the first detuned DBR, a phase deviation substantially equal to π/2, and wherein the second detuned DBR is configured to induce, in the optical field of the emission wavelength propagating through the second detuned DBR, a phase deviation substantially equal to π/2.
Aspect 20: The emitter of any of Aspects 18-19, wherein the first detuned DBR and the second detuned DBR, in combination, are configured to induce a reflectance curve defining a pass-band or a minimum reflection region that is aligned with the emission wavelength.
Aspect 21: The emitter of any of Aspects 18-20, further comprising: an intermediate DBR mirror arranged between the first detuned DBR and the second detuned DBR, the intermediate DBR mirror characterized by a fifth reflectance curve that defines a fifth optical stop-band having a fifth center wavelength substantially aligned with the emission wavelength.
Aspect 22: The emitter of Aspect 21, wherein the first detuned DBR, the second detuned DBR, and the intermediate DBR, in combination, are configured to induce a reflectance curve defining a pass-band or a minimum reflection region that is aligned with the emission wavelength.
Aspect 23: The emitter of any of Aspects 18-22, wherein the first detuned DBR is arranged closer to the active region than the second detuned DBR, and wherein the first detuned DBR and the second detuned DBR, in combination, are configured to cause an optical field peak intensity over a combined length of the first detuned DBR and the second detuned DBR to firstly decrease based on light entering the first detuned DBR from the active region, subsequently increase to form at least one peak as the light propagates through the second detuned DBR, and subsequently decrease as the light exists the second detuned DBR.
Aspect 24: A system configured to perform one or more operations recited in one or more of Aspects 1-23.
Aspect 25: An apparatus comprising means for performing one or more operations recited in one or more of Aspects 1-23.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An emitter, comprising:
a bottom distributed Bragg reflector (DBR) mirror, the bottom DBR mirror characterized by a first reflectance curve that defines a first optical stop-band having a first center wavelength substantially aligned with an emission wavelength;
a top DBR mirror arranged on the bottom DBR mirror, the top DBR mirror characterized by a second reflectance curve that defines a second optical stop-band having a second center wavelength substantially aligned with the emission wavelength;
an active region formed by one or more active layers comprising one or more junctions, each junction including one or more quantum wells, wherein the active region is configured to generate laser light at the emission wavelength, and wherein the active region is arranged between the top DBR mirror and the bottom DBR mirror;
a first detuned DBR arranged between the bottom DBR mirror and the active region or between the top DBR mirror and the active region, the first detuned DBR characterized by a third reflectance curve that defines a third optical stop-band and a minimum reflection region, wherein the third optical stop-band is offset from the emission wavelength, and wherein the minimum reflection region is aligned with the emission wavelength; and
an optical output arranged over the top DBR mirror, wherein the emitter is configured to emit the laser light via the optical output.

2. The emitter of claim 1, wherein the minimum reflection region is a first minimum reflection region located directly between the third optical stop-band and a first side-lobe of the third reflectance curve.

3. The emitter of claim 2, wherein the bottom DBR mirror, the top DBR mirror, the first detuned DBR, and the active region define an optical cavity of the emitter, and
wherein the first detuned DBR is configured to cause an envelope of an optical field peak intensity to exhibit a gradually-changing outline with a single peak over a length of the first detuned DBR.

4. The emitter of claim 1, wherein the minimum reflection region is a second minimum reflection region located directly between a first side-lobe of the third reflectance curve and a second side-lobe of the third reflectance curve.

5. The emitter of claim 4, wherein the bottom DBR mirror, the top DBR mirror, the first detuned DBR, and the active region define an optical cavity of the emitter, and
wherein the first detuned DBR is configured to cause an envelope of an optical field peak intensity to exhibit a gradually-changing outline with two peaks over a length of the first detuned DBR.

6. The emitter of claim 1, wherein the bottom DBR mirror, the top DBR mirror, and the active region define an optical cavity of the emitter, and
wherein the first detuned DBR is configured to increase an effective cavity length of the optical cavity.

7. The emitter of claim 1, wherein the first detuned DBR is configured to cause an optical field peak intensity over a length of the first detuned DBR to firstly decrease based on light entering the first detuned DBR from the active region, subsequently increase to form at least one peak as the light propagates through the first detuned DBR, and subsequently decrease as the light exists the first detuned DBR.

8. The emitter of claim 1, wherein the first detuned DBR has an optical thickness deviation that is offset from a half-wavelength integer of the emission wavelength.

9. The emitter of claim 1, wherein the first detuned DBR comprises a plurality of high and low refractive index layer pairs, and
wherein the first detuned DBR has a total optical thickness that is evenly distributed among the plurality of high and low refractive index layer pairs.

10. The emitter of claim 1, wherein the first detuned DBR comprises a plurality of high and low refractive index layer pairs, and
wherein the first detuned DBR has a total optical thickness that is unevenly distributed among the plurality of high and low refractive index layer pairs.

11. The emitter of claim 1, wherein the first detuned DBR induces, in an optical field of the emission wavelength propagating through the first detuned DBR, a phase deviation substantially equal to π or substantially equal to an integer of π.

12. The emitter of claim 1, further comprising:
a second detuned DBR arranged between the top DBR mirror and the active region, the second detuned DBR characterized by a fourth reflectance curve that defines a fourth optical stop-band and a further minimum reflection region, wherein the fourth optical stop-band is offset from the emission wavelength, and wherein the further minimum reflection region of the second detuned DBR is aligned with the emission wavelength,
wherein the first detuned DBR is arranged between the bottom DBR mirror and the active region.

13. The emitter of claim 12, wherein the first detuned DBR and the second detuned DBR are configured to increase an effective cavity length of the emitter.

14. An emitter, comprising:
a bottom distributed Bragg reflector (DBR) mirror, the bottom DBR mirror characterized by a first reflectance curve that defines a first optical stop-band having a first center wavelength substantially aligned with an emission wavelength;
a top DBR mirror arranged on the bottom DBR mirror, the top DBR mirror characterized by a second reflectance curve that defines a second optical stop-band having a second center wavelength substantially aligned with the emission wavelength;
an active region formed by one or more active layers comprising one or more junctions, each junction including one or more quantum wells, wherein the active region is configured to generate laser light at the emission wavelength, and wherein the active region is arranged between the top DBR mirror and the bottom DBR mirror;
a first detuned DBR arranged between the bottom DBR mirror and the active region or between the top DBR mirror and the active region,
wherein the bottom DBR mirror, the top DBR mirror, the first detuned DBR, and the active region define an optical cavity of the emitter, and
wherein the first detuned DBR is configured to increase an effective cavity length of the optical cavity; and
an optical output arranged over the top DBR mirror, wherein the emitter is configured to emit the laser light via the optical output.

15. The emitter of claim 14, further comprising:
a spacer arranged proximate to the first detuned DBR,
wherein the first detuned DBR and the spacer, in combination, are configured to induce a reflectance curve defining a pass-band or a minimum reflection region that is aligned with the emission wavelength, and/or
wherein the first detuned DBR and the spacer, in combination, are configured to induce, in an optical field of the emission wavelength propagating through the spacer and the first detuned DBR, a phase deviation substantially equal to π or substantially equal to an integer of π.

16. The emitter of claim 14, wherein the first detuned DBR is characterized by a third reflectance curve that defines a pass-band aligned with the emission wavelength.

17. The emitter of claim 16, wherein the pass-band is a first minimum reflection region located directly between an optical stop-band of the third reflectance curve and a first side-lobe of the third reflectance curve, or
wherein the pass-band is a second minimum reflection region located directly between the first side-lobe of the third reflectance curve and a second side-lobe of the third reflectance curve.

18. An emitter, comprising:
a bottom distributed Bragg reflector (DBR) mirror, the bottom DBR mirror characterized by a first reflectance curve that defines a first optical stop-band having a first center wavelength substantially aligned with an emission wavelength;
a top DBR mirror arranged on the bottom DBR mirror, the top DBR mirror characterized by a second reflectance curve that defines a second optical stop-band having a second center wavelength substantially aligned with the emission wavelength;
an active region formed by one or more active layers comprising one or more junctions, each junction including one or more quantum wells, wherein the active region is configured to generate laser light at the emission wavelength, and wherein the active region is arranged between the top DBR mirror and the bottom DBR mirror;
a first detuned DBR arranged between the bottom DBR mirror and the active region or between the top DBR mirror and the active region, the first detuned DBR characterized by a third reflectance curve;
a second detuned DBR arranged between the bottom DBR mirror and the active region or between the top DBR mirror and the active region, the second detuned DBR characterized by a fourth reflectance curve,
wherein the first detuned DBR and the second detuned DBR, in combination, are configured to induce, in an optical field of the emission wavelength propagating through the first detuned DBR and the second detuned DBR, a phase deviation substantially equal to π or substantially equal to an integer of π; and
an optical output arranged over the top DBR mirror, wherein the emitter is configured to emit the laser light via the optical output.

19. The emitter of claim 18, wherein the first detuned DBR is configured to induce, in the optical field of the emission wavelength propagating through the first detuned DBR, a phase deviation substantially equal to π/2, and
wherein the second detuned DBR is configured to induce, in the optical field of the emission wavelength propagating through the second detuned DBR, a phase deviation substantially equal to π/2.

20. The emitter of claim 18, wherein the first detuned DBR and the second detuned DBR, in combination, are configured to induce a reflectance curve defining a pass-band or a minimum reflection region that is aligned with the emission wavelength.

21. The emitter of claim 18, further comprising:
an intermediate DBR mirror arranged between the first detuned DBR and the second detuned DBR, the intermediate DBR mirror characterized by a fifth reflectance curve that defines a fifth optical stop-band having a fifth center wavelength substantially aligned with the emission wavelength.

22. The emitter of claim 21, wherein the first detuned DBR, the second detuned DBR, and the intermediate DBR, in combination, are configured to induce a reflectance curve defining a pass-band or a minimum reflection region that is aligned with the emission wavelength.

23. The emitter of claim 18, wherein the first detuned DBR is arranged closer to the active region than the second detuned DBR, and
wherein the first detuned DBR and the second detuned DBR, in combination, are configured to cause an optical field peak intensity over a combined length of the first detuned DBR and the second detuned DBR to firstly decrease based on light entering the first detuned DBR from the active region, subsequently increase to form at least one peak as the light propagates through the second detuned DBR, and subsequently decrease as the light exists the second detuned DBR.
